(19) United States
(12) Patent Application Publication
(10) Pub. No.: US 2017/0256436 A1
(43) Pub. Date: Sep. 7, 2017

(54) WAFER HANDLING ASSEMBLY

(71) Applicant: Veeco Instruments, Inc., Plainview, NY (US)

(72) Inventors: Yuliy Rashkovsky, Millburn, NJ (US); Brett Stuart Snowden, Manasquan, NJ (US); Miguel Angel Saldana, Princeton, NJ (US)

(21) Appl. No.: 15/057,530

(22) Filed: Mar. 1, 2016

(51) Int. Cl. H01L 21/687; B25J 15/00; B25J 11/00; H01L 21/683

(52) U.S. Cl. CPC H01L 21/68742; H01L 21/6838; B25J 15/0028; B25J 15/0052; B25J 11/0095

(57) ABSTRACT

A wafer handing assembly comprising a center hub supporting a vertical non-contact lifting head and at least one radially extending and radially retracting wafer engaging mechanism having a surface to engage a wafer at a peripheral edge of the wafer, where the peripheral edge is a corner edge or a side edge. In some implementations, the wafer engaging mechanism has a foot on which the wafer edge is supported.

### BACKGROUND

Users of wafer handling and processing equipment would like the systems to be fairly simple and inexpensive, operate quickly and efficiently, be able to operate with minimal contamination (e.g., particle) creation, and have a short transfer time in order to minimize cycle time, all with minimal operator intervention. Various systems are known for handling wafers within the semiconductor processing system, including robotic systems that maneuver the wafer as needed. Improvements, however, are needed.

### SUMMARY

The described technology is directed to a wafer handling assembly, system and method, particularly, a handling assembly, system and methods for moving a wafer into and out from a wafer carrier.

One particular implementation described herein is a wafer handing assembly comprising a center hub supporting a vertical lifting head and at least three radially extending and radially retracting wafer engaging mechanisms each having a surface to engage a wafer at a peripheral edge of the wafer.

Another particular implementation described herein is wafer handling assembly comprising a non-contact vertical lifting head, at least one arm configured to radially extend and radially retract in relation to the lifting head, and a wafer engaging mechanism comprising a wafer receiving region and an alignment pin at a distal end of the arm, the wafer receiving region defined by a lower toe.

Yet another particular implementation described herein is a wafer handling assembly comprising a center hub supporting a vertical lifting head and having extending radially therefrom at least one arm, where the center hub, the vertical lifting head and the at least one radially extending arm define a volume for receiving a wafer therein. The assembly further comprises a wafer engaging mechanism on the at least one arm, the wafer engaging mechanism configured to radially move in relation to the center hub, the wafer engaging mechanism comprising a foot having a support for receiving a lower edge of the wafer and an alignment feature for engaging a peripheral edge of the wafer.

Yet another particular implementation described herein is a wafer handling assembly comprising a center hub supporting a vertical lifting head and at least one radially extending and radially retracting arm, the arm supporting a wafer engaging mechanism comprising a foot defining a wafer receiving region and an alignment pin.

A particular implementation of a method described herein comprises providing a wafer on a carrier, non-contactingly engaging the top surface of the wafer with a lifting head, lifting the wafer from the carrier with the lifting head, and after lifting the wafer, contacting the bottom peripheral corner edge or peripheral side edge with a wafer engaging mechanism and then releasing the wafer from the lifting head.

These and various other implementations, features and advantages will be apparent from a reading of the following detailed description.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWING

FIG. 1 is a top, perspective view of an implementation of a wafer handling assembly.

FIG. 2 is a bottom, perspective view of the assembly of FIG. 1.

FIG. 3 is a top, perspective view of the assembly of FIG. 1, showing internal features of the wafer handling assembly as well as a wafer carrier with a wafer therein.

FIG. 4 is a side, cross-sectional view of a wafer engaging mechanism of the assembly of FIG. 1 supporting the wafer.

FIG. 5 is a top plane view of the wafer and wafer engaging mechanism from the assembly of FIG. 1.

FIG. 6 is a top, perspective view of another implementation of a wafer handling assembly, also showing a wafer.

FIG. 7 is a cross-sectional view of the wafer handling assembly of FIG. 6.

FIG. 8 is an enlarged, side plane view of a wafer engaging mechanism of the assembly of FIG. 6 supporting the wafer.

FIG. 9 is a perspective view of an alignment feature of the wafer engaging mechanism.

FIG. 10 is a side cross-sectional view of the shroud of the assembly of FIG. 6.

FIG. 11 is a flow chart illustrating stepwise an example method for moving a wafer with a wafer handling assembly.

FIG. 12 is a top, perspective view of another implementation of a wafer handling assembly, also showing a wafer carrier with a wafer therein.

FIG. 13 is a top, perspective view of the assembly of FIG. 12, showing internal features of the wafer handling assembly.

FIG. 14 is a side, plane view of a wafer engaging mechanism from the assembly of FIG. 12 engaged with the wafer.

FIGS. 15A, 15B and 15C are side, plane views illustrating stepwise an example method for placing a wafer into a wafer carrier.

FIGS. 16A, 16B and 16C are side, plane views illustrating stepwise an example method for lifting a wafer out from a wafer carrier.

FIGS. 17A-17Q are various views of three embodiments of a wafer engaging mechanism.

FIGS. 18A-18Q are various views of three embodiments of an alternate wafer engaging mechanism.

FIGS. 19A-19G are various views of an embodiment of a slideable member.

FIGS. 20A-20N are various views of five embodiments of an alignment member.

FIGS. 21A-21D are various views of an embodiment of a shroud.

FIGS. 22A-22G are various views of a first part of an embodiment of a rotatable cam.

FIGS. 23A-23G are various view of a second part of an embodiment of a rotatable cam.

FIG. 24 is a perspective view of a rotatable cam formed by the first part of FIGS. 22A-22G assembled with the second part of FIGS. 23A-23G.

### DETAILED DESCRIPTION

The present description is directed to wafer handling assemblies, and methods, particularly wafer handling assemblies and methods for moving a wafer (e.g., a silicon wafer, a sapphire wafer) into and out from a wafer carrier by using a vertically-oriented lifting head (e.g., a non-contact a vertically-oriented lifting head) and a wafer engaging mechanism at an outer periphery of a wafer substrate. The wafer engaging mechanism moves radially outwardly and retracts radially inwardly to engage with the wafer proximate its outer periphery. In some implementations, the lower peripheral corner edge of the wafer is contacted by the wafer engaging mechanism, whereas in other implementations the top peripheral corner edge of the wafer is also contacted. In other implementations, the peripheral side edge or wall of the wafer is contacted by the wafer engaging mechanism.

The wafer handling assemblies are used in or with a wafer processing system, such as a CVD (chemical vapor deposition) system, MOCVD (metal organic CVD) system, ion beam deposition system, chemical etching system, ion milling system, physical vapor deposition (PVD) system, DLC (diamond-like carbon) deposition system, or other processing systems. The wafer processing system includes a robotic handling system (e.g., referred to as an automated factory interface) for loading and unloading wafers, seated on their carrier, into and out of a chamber, such as a loadlock chamber. Although the wafer handling assemblies of this disclosure may be present in any portion of a wafer processing system, the assemblies will typically be part of or connected to an atmospheric robotic system that loads and unloads wafers in a loadlock chamber of a wafer processing system, such as a MOCVD system.

In the following description, reference is made to the accompanying drawing that forms a part hereof and in which are shown by way of illustration at least one specific implementation. The following description provides additional specific implementations. It is to be understood that other implementations are contemplated and may be made without departing from the scope or spirit of the present invention. The following detailed description, therefore, is not to be taken in a limiting sense. While the present invention is not so limited, an appreciation of various aspects of the invention will be gained through a discussion of the examples provided below.

As used herein, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

Spatially related terms, including but not limited to, “lower”, “upper”, “beneath”, “below”, “above”, “on top”, etc., if used herein, are utilized for ease of description to describe spatial relationships of an element(s) to another. Such spatially related terms encompass different orientations of the device in addition to the particular orientations depicted in the figures and described herein. For example, if a structure depicted in the figures is turned over or flipped over, portions previously described as below or beneath other elements would then be above or over those other elements.

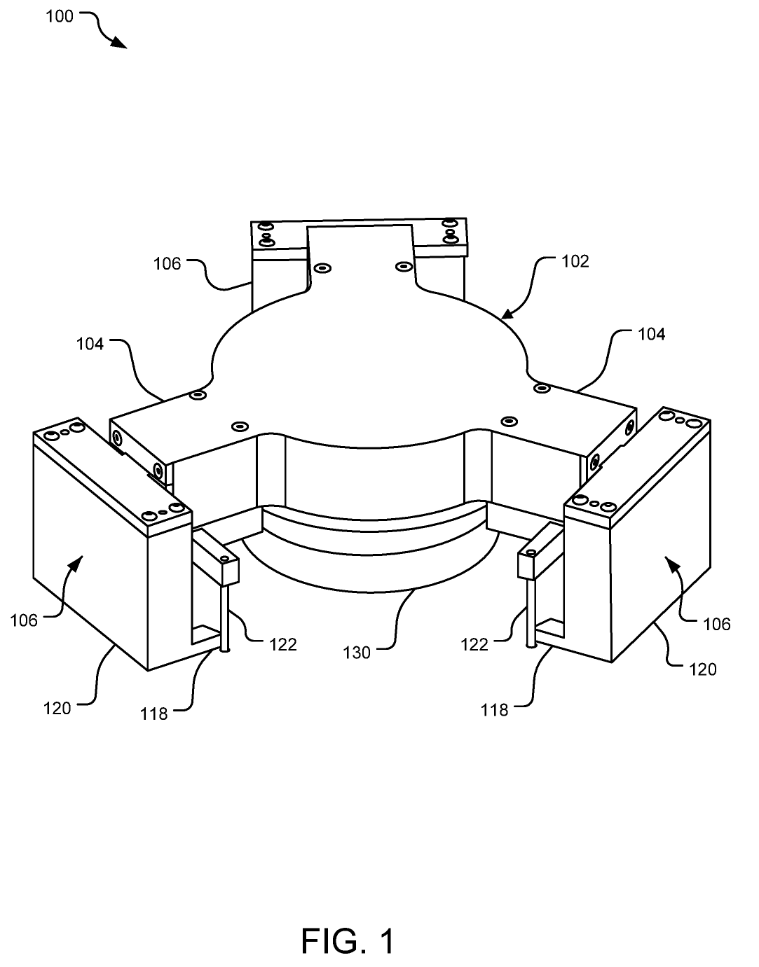

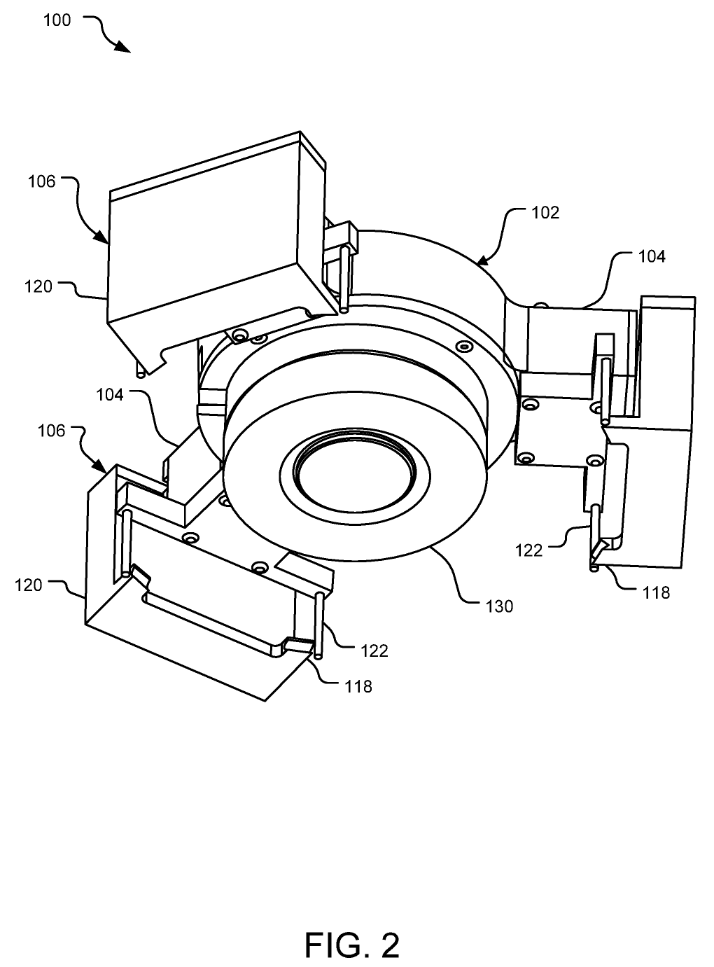

FIGS. 1 through 5 illustrate a first implementation of a wafer handling assembly 100 configured for removing a wafer (e.g., a silicon wafer, a sapphire wafer) from a wafer carrier; in some implementations, the wafer handling assembly 100 is configured for removing a wafer from a recess in the wafer carrier. The wafer handling assembly 100 has a vertically-oriented lifting head that removes the wafer from the carrier (e.g., from the recess in the carrier) and at least one wafer engaging mechanism that receives the wafer from the lifting head. Additionally, the wafer handling assembly 100 is configured for placing a wafer on a wafer carrier using the at least one wafer engaging mechanism; in some implementations, the wafer handling assembly 100 is configured for placing a wafer in a recess in the wafer carrier. In some implementations, both the at least one wafer engaging mechanism and the lifting head are used to place the wafer on the carrier (e.g., in the recess of the carrier).

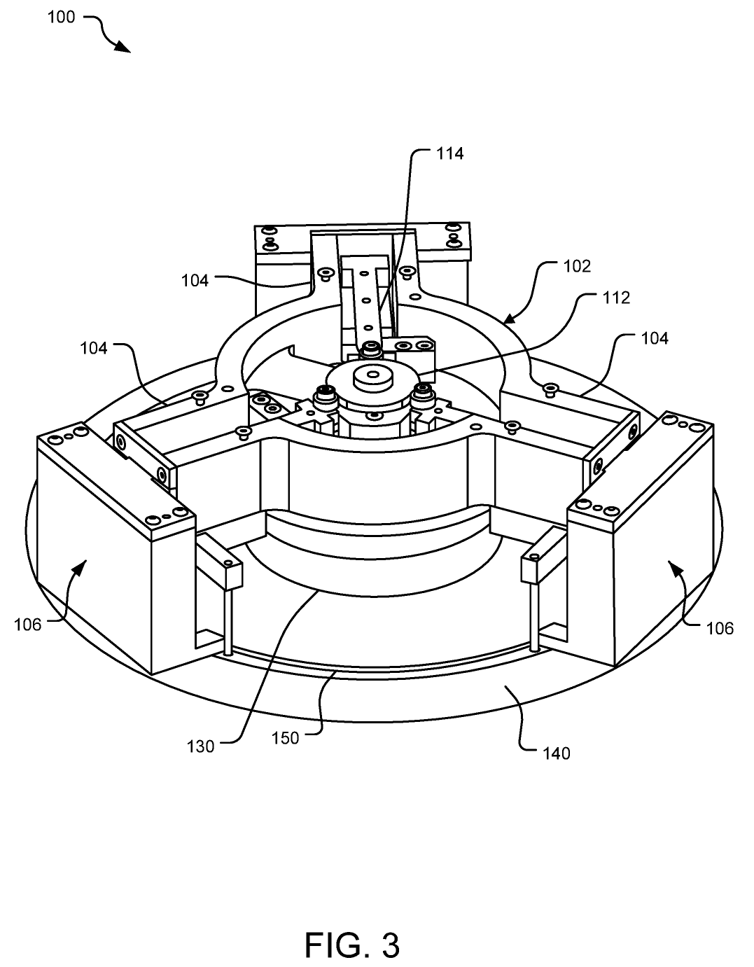

Referring particularly to FIGS. 1, 2 and 3, the wafer handling assembly 100 has a center hub 102 from which extends at least one radially extending arm 104 that has a wafer engaging mechanism 106 supported thereby, typically at or proximate to the distal end of the arm 104. In the particular implementation, the assembly 100 has three equally spaced radially extending arms 104, although in other implementations less or more arms 104 may be present, with the multiple arms equally spaced or not. For example, a wafer handling assembly may have four equally spaced arms. The hub 102 and the radially extending arms 104 define a volume for receiving a wafer therein; see, e.g., FIG. 3 where a wafer 150 is shown in the wafer handling assembly 100.

Each of the arms 104 is radially extendible out from and retractable in toward the center hub 102, to thus extend the length of the arm 104 and decrease the length of the arm 104, respectively. In some implementations, only a portion (e.g., an internal shaft) extends and retracts in relation to the hub 102, rather than the entire arm 104; what is intended is the overall length of the arm 104 increases and decreases, to thus move the wafer engaging mechanism 106 radially in relation to the hub 102. Typically, multiple arms 104 will extend and retract simultaneously and in unison.

Seen in FIG. 3, positioned at the radial center of hub 102 is a rotatable cam 112, in this implementation configured as a disc with three essentially flat portions, the flat portions closer to the center of the disc than the other surfaces of the disc; that is, the flat portions have a radius from the center of the disc that is less than the radius of the other portions. There is at least one flat portion for each arm 104, and although in other implementations the cam 112 may have more flat portions than there are arms 104, typically the number of flat portions will be the same as the number of arms 104. Other designs may be used for the cam 112.

Each arm 104 has a moveable internal shaft 114, with the wafer engaging mechanism 106 connected at or proximate to its distal end. The end opposite to the distal end (also referred to as the proximal end) of internal shaft 114 is moveably (e.g., slideably) seated against the rotatable cam 112. As the cam 112 rotates, the shaft 114 slides along the surface of the cam 112 following the contour of the cam 112; thus, the shaft 114 slides radially in and out as the proximal end of the shaft 114 moves from the flat portion(s) to the radiused portion(s) of the cam 112. When the shaft 114 contacts a flat portion, the shaft 114 and thus the wafer engaging mechanism 106 retract inward, and when the shaft 114 contacts a radiused portion, the shaft 114 and thus the wafer engaging mechanism 106 extend outward. In alternate implementations, the arm 104 and/or the shaft 114 may be moved (i.e., retracted and extended) in relation to the hub 102 pneumatically, hydraulically, electrically, or by other mechanical mechanisms, such as springs, belts, levers, etc.

The wafer engaging mechanism 106 engages the wafer 150 after the wafer 150 has been removed from a substrate carrier 140 by a vertically-oriented lifting head 130 or before the wafer 150 is placed on the substrate carrier 140, such as by the vertically-oriented lifting head 130. In typical implementations, the substrate carrier 140 has at least one recessed portion that is dimensioned to receive the wafer 150. The diameter of the recess is just slightly bigger than the diameter of the wafer 150 and will differ depending on various factors such as the temperature of the wafer 150, the temperature of the carrier 140, and the coefficient of expansion of the materials that form the wafer 150 and the carrier 140. Because of the small gap between the outer edge of the wafer 150 and the recess, the wafer engaging mechanism 106 is not able to readily access the periphery of the wafer 150 to remove the wafer 150 from the carrier recess. For this reason, the lifting head 130 is used to remove the wafer 150 from the recess of the carrier 140. However typically, the lifting head 130 consumes a large amount of compressed gas (e.g., air or nitrogen). To reduce the costs associated with the operation of the lifting head 130, the use of the lifting head 130 is minimized; once the wafer 150 is removed from the carrier by the lifting head 130, the wafer engaging mechanism 106 takes the wafer 150 and the lifting head 130 is deactivated.

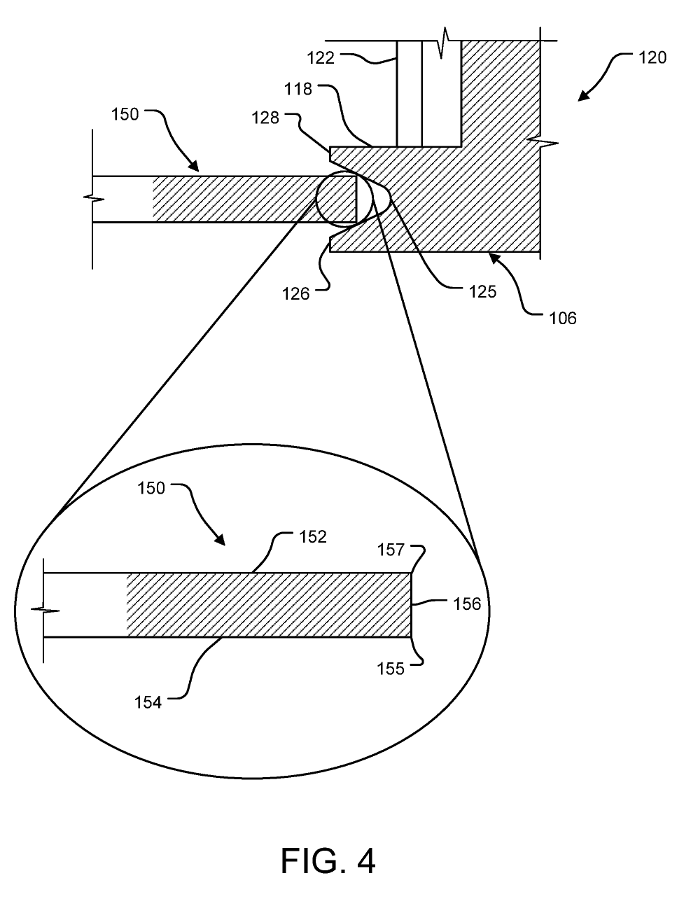

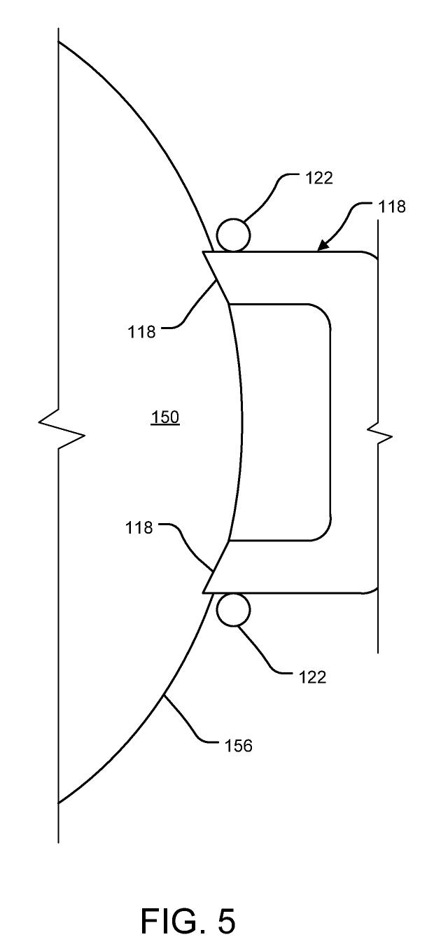

The wafer engaging mechanism 106 includes a foot 118 supported by a leg 120, configured to support the wafer 150 at least by its bottom peripheral corner edge (i.e., a peripheral corner edge proximate the carrier 140). The wafer engaging mechanism 106 also includes an alignment feature 122, such as a pin, to laterally constrain the wafer 150 in or on the foot 118. FIGS. 4 and 5 provide an enlarged view of the wafer engaging mechanism 106.

As described above, at or near the distal end of the arm 104, which extends radially across the wafer, is the wafer engaging mechanism 106. In general, the wafer engaging mechanism 106 is positioned, both in its retracted and extended position, outside of the periphery of the wafer 150. In some implementations, when the arm 104 is extended, all features of the wafer engaging mechanism 106 (i.e., the leg 120, the foot 118, and the alignment feature 122) are outside of the periphery of the wafer 150. Both FIG. 4 and FIG. 5 show the wafer engaging mechanism 106 engaged with the wafer 150, with only a portion (e.g., a tip) of the foot 118 (or, feet 118) not outside the periphery of the wafer 150. As seen in FIG. 5, the wafer engaging mechanism 106 has two feet 118, one at each side of the wafer engaging mechanism 106; in other implementations, the wafer engaging mechanism 106 may have only one foot 118 or have more than two feet 118.

The inset of FIG. 4 shows the wafer 150 with its top surface 152, its bottom surface 154, and peripheral side edge 156 called out; the top surface 152 is the surface of the wafer 150 that has or will eventually be processed, e.g., patterned, and the bottom surface 154 is the surface in contact with the wafer carrier 140. The top surface 152 meets the side edge 156 at a top or upper peripheral corner edge 157 and the bottom surface 154 meets the side edge 156 at a bottom peripheral corner edge 155.

Best seen in FIG. 4, the foot 118 has a lower toe 126 and an upper toe 128 that define a wafer engaging region 125 that receives the wafer 150. The wafer 150 is retained in the wafer engaging region 125 between the lower toe 126 and the upper toe 128. In this particular implementation, each of the lower toe 126 and the upper toe 128 are angled, forming a tapered wafer engaging region 125. The wafer 150 is supported by its lower peripheral corner edge 155 on the lower toe 126 and the upper toe 128 inhibits upward movement of the wafer 150 by engaging the upper peripheral corner edge 157 of the wafer 150. See also FIG. 5, which shows a portion of the upper toe 128 extending over the wafer 150. Although in this particular implementation of the foot 118 and the wafer engaging region 125, the peripheral side edge 156 of the wafer 150 is not contacted by the wafer engaging region 125, in other implementations the wafer engaging region 125 is shaped and sized to contact the peripheral side edge 156.

As indicated above, the alignment feature 122 can be used to adjust the position of the wafer 150, e.g., to center the wafer 150 among the legs 120 and wafer engaging mechanisms 106. The alignment feature 122 can additionally be used to control the depth of the wafer 150 into the wafer engaging region 125, e.g., so that the peripheral side edge 156 does not contact the wafer engaging region 125.

The wafer engaging mechanism 106 engages the wafer 150 when the wafer 150 is out from the substrate carrier 140, e.g., after the wafer 150 has been removed from the substrate carrier 140 by the vertically-oriented lifting head 130.

The lifting head 130 non-contactingly engages the top surface 152 of the wafer 150 and moves (e.g., lifts) the wafer 150 off of the substrate carrier 140, e.g., out from the recess in the substrate carrier 140. In some implementations, the lifting head 130 may additionally lower the wafer 150 onto the carrier 140 with or without the aid of the wafer engaging mechanism 106. The lifting head 130 is centered under the hub 102, axially aligned with the rotatable cam 112 that extends and retracts the arms 104. In some implementations, the vertically-oriented lifting head 130 has an auto-aligning feature, to facilitate properly aligning and/or centering the wafer 150 during movement of the wafer 150. In some implementations, the lifting head 130 is moveable in relation to the hub 102, e.g., axially (i.e., up and down, or toward and away) in relation to the center hub 102.

One implementation of a suitable lifting head 130 is a Bernoulli head, alternately called a Bernoulli wand. A Bernoulli head has a plurality of gas outlets configured to produce a flow of gas (e.g., air, nitrogen) along an upper surface 152 of the wafer 150 to create a pressure differential between the upper surface 152 of the wafer and the lower surface 154 of the wafer. The pressure differential generates a lift force that supports the wafer 150 below the head 130 in a substantially non-contacting manner, employing the Bernoulli principle.

Another implementation of a suitable lifting head 130 is an ultrasound-air bearing lifting head, which is another technology of non-contact lifting. Such heads, based on ultrasonic suspension technology, are available, for example, from ZS-Handling, GmbH.

Other suitable heads 130 and mechanisms to lift the wafer 150 include electrostatic force(s), magnetic force(s), vacuum or pressure, and pneumatic force(s).

Not shown in FIG. 1 or any of the other figures, a robotic arm with an end effector can be used to move the wafer 150 and the substrate carrier 140 to and from the assembly 100. The end effector may be, for example, a straight fork or a curved or arcuate fork, having, e.g., 2 or 4 tines, or a paddle. Other designs for the end effector include those with a vacuum suction mechanism or with an edge grip mechanism. Additionally or alternately, the wafer handling assembly 100 may be attached to a translation stage or a robotic system that moves the assembly 100.

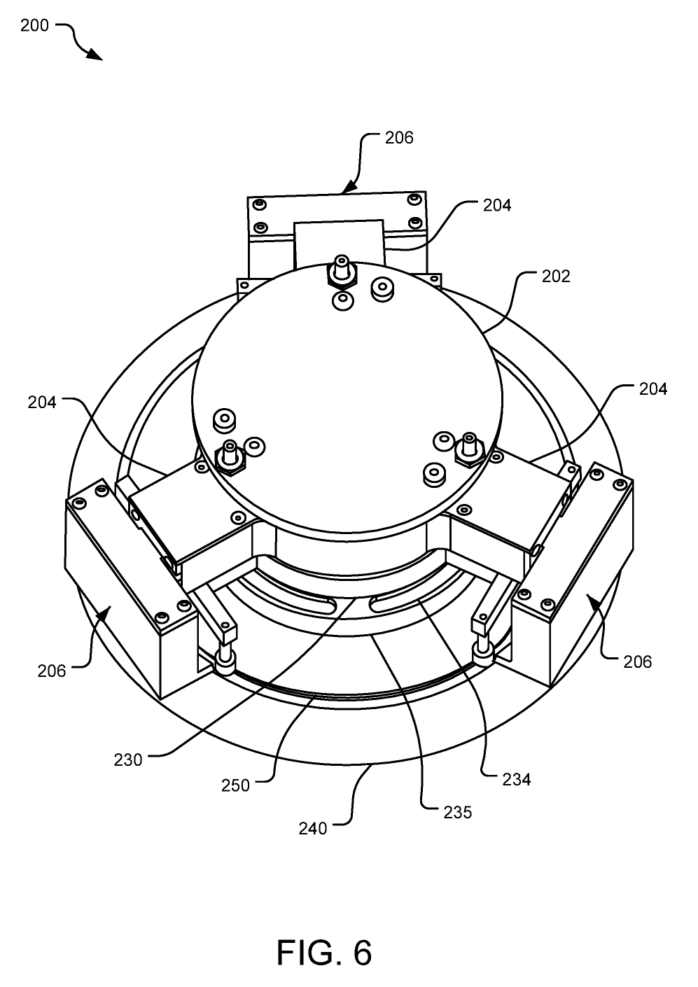

FIGS. 6 through 10 illustrate a second implementation of a wafer handling assembly 200 configured for removing and/or placing a wafer (e.g., a silicon wafer, a sapphire wafer) onto a wafer carrier; in some implementations, the wafer handling assembly 200 is configured for removing and/or placing a wafer from a recess in a wafer carrier. Unless indicated otherwise, the various features and/or elements of the assembly 200 are the same as or similar to the like-number features and/or elements of the assembly 100 described above. It should be understood that features and/or elements from one assembly 100, 200 can be incorporated into the other assembly 100, 200.

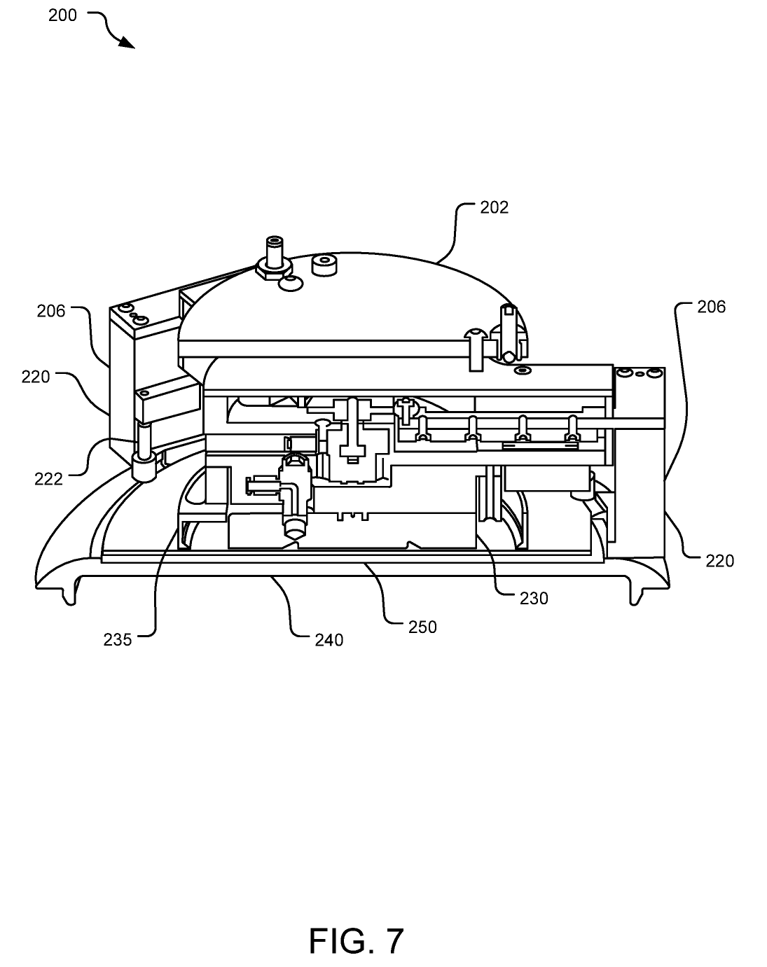

Similar to the wafer handling assembly 100, the wafer handling assembly 200 (best seen in FIGS. 6 and 7) has a center hub 202 from which extends at least one radially extending arm 204 that has a wafer engaging mechanism 206 supported thereby, typically at or proximate to the distal end of the arm 204. In the particular implementation, the wafer handling assembly 200 has three equally spaced radially extending arms 204. Each of the arms 204, and thus each wafer engaging mechanism 206, is radially extendible out from and retractable in toward the center hub 202. The wafer engaging mechanism 206 engages with a wafer 250.

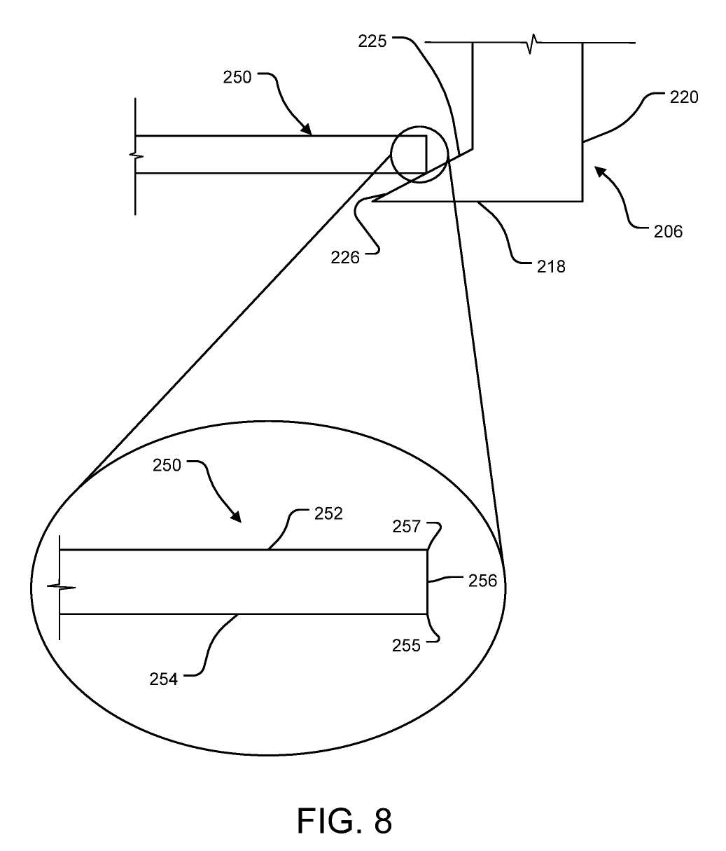

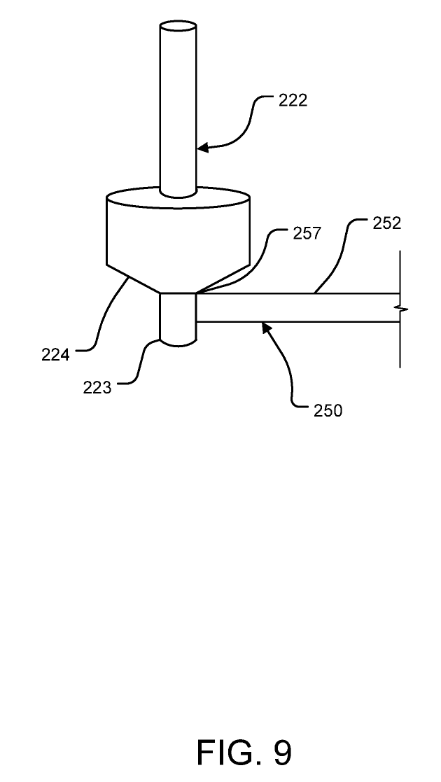

The wafer engaging mechanism 206 includes a foot 218 supported by a leg 220, to support the wafer 250 at least by its bottom peripheral corner edge. The wafer engaging mechanism 206 also includes an alignment feature 222, such as a pin, to constrain the wafer 250 (e.g., laterally constrain) in or on the foot 218. The arrangement of the foot 218, the leg 220 and the alignment feature 222 in the wafer engaging mechanism 206 are seen, e.g., in FIG. 6 and FIG. 7. FIG. 8 provides an enlarged view of the wafer engaging mechanism 206, particularly the foot 218 and the leg 220, and FIG. 9 provides an enlarged view of the alignment feature 222.

Referring to FIGS. 8 and 9, as in the assembly 100 described above, the wafer engaging mechanism 206 has two feet 218 on the leg 220, although in other implementations only one foot 218 may be present. Each foot 218 has a wafer engaging region 225 that receives the periphery of the wafer 250. The wafer engaging region 225 of the foot 218 has a lower toe 226 on which is supported the wafer 250.

The inset of FIG. 8 shows the wafer 250 with its top surface 252, its bottom surface 254, and its peripheral side edge 256 called out. The top surface 252 meets the side edge 256 at a top or upper peripheral corner edge 257 and the bottom surface 254 meets the side edge 256 at a bottom peripheral corner edge 255. In this implementation, the wafer 250 is supported on the lower toe 226 and contacts the wafer engaging region 225 only at the bottom peripheral corner edge 255.

As indicated above, the alignment feature 222 can be used to control the depth of the wafer 250 into the wafer engaging region 225 and/or to adjust the position of the wafer 250 in relation to the center hub 202 and the legs 220 and wafer engaging mechanisms 206. In this particular implementation, the alignment feature 222 also inhibits upward movement of the wafer 250 by engaging the upper peripheral corner edge 257 of the wafer 250 with a shoulder 224; see, FIG. 9, which shows the alignment feature 222 with an angled surface as the shoulder 224 and the upper peripheral corner edge 257 of the wafer 250 seated thereagainst. With an angled surface such as the shoulder 224, the corner edge 257 of the wafer contacts the alignment feature 222 without the top surface 252 of the wafer 250 contacting the alignment feature 222.

Although the bottom portion of the alignment feature 222, called out as tip 223 in FIG. 9, is illustrated as straight at a right angle with a flat lower surface, any portion to the tip 223 may be tapered or chamfered optionally having a radiused transition to the lower surface, which may be e.g., flat, pointed, or semi-hemispherical (e.g., radiused).

Retuning to FIGS. 6 and 7, the assembly 200 also includes a shroud 235 in close proximity to the lifting head 230 and encircling the lifting head 230. The shroud 235 is a baffle, controlling the fluid (e.g., air, gas) flow around the lifting head 230. For example, a Bernoulli head has numerous gas outlets through which gas (e.g., compressed gas) exits and flows along the upper surface 252 of the wafer 250, producing various gas currents across the upper surface 252 of the wafer 250. These currents outside the lifting head can undesirably carry and distribute across the surface 252 contaminants (such as particulates that may have been formed or carried over from the processing, dust present in the air, and/or gases that may have carried over from the processing). By having the shroud 235, gas flow from the lifting head 230 does not flow across the surface 252 of the wafer 250, but rather, is controlled. The particular shroud 235 illustrated, best seen in FIG. 6, has exhaust ports 234 to remove the gas away from the wafer surface 252.

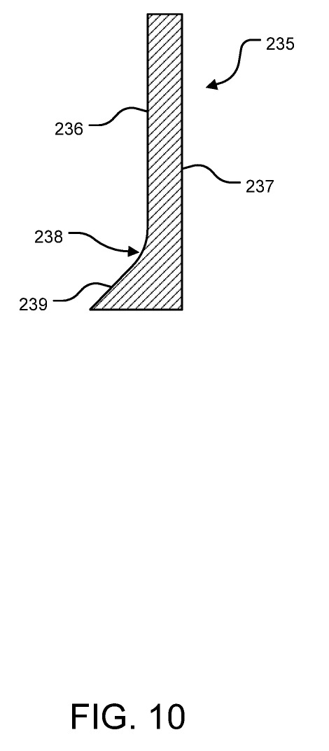

FIG. 10 illustrates a close-up profile of the shroud 235. The shroud 235 has an inner surface 236 and an opposite outer surface 237, the inner surface 236 being closer to the lifting head 230 than the outer surface 237. The inner surface 236 has a profile 238 designed to urge the flow of gas away from the wafer surface. The profile 238 includes a ramped portion 239 that initiates the flow of gas from the wafer surface upwards, and can include other features, such as a radiused portion and/or a vertical portion, to facilitate the upward flow of gas.

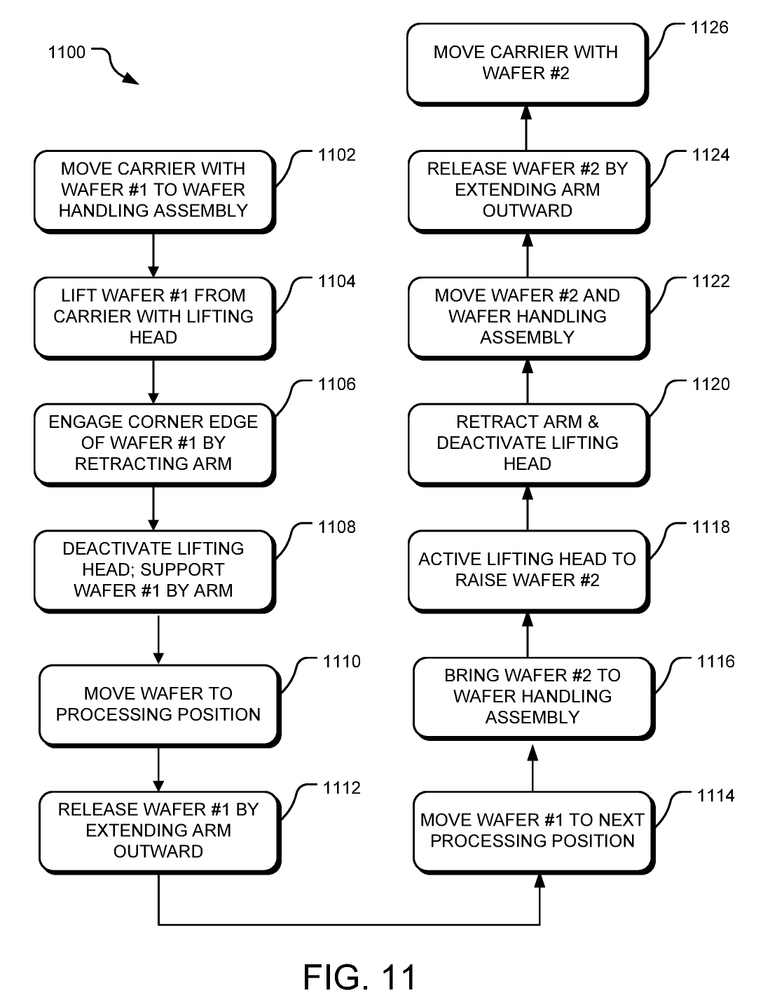

FIG. 11 shows a flow diagram of an example method 1100 for moving a wafer using a wafer handling assembly (e.g., assembly 100, 200).

In a first operation 1102, a substrate carrier with a processed wafer (wafer #1) seated in a recess is moved under a wafer handling assembly (e.g., assembly 100, 200) by a factory transport mechanism such as an end effector. This occurs at a first location.

Once the wafer sitting in the carrier recess is under the wafer handling assembly in the first location, a lifting head (e.g., a non-contact lifting head, such as a Bernoulli head) is activated in operation 1104, and the processed wafer #1 is lifted out of the recess by the lifting head. In some implementations, unmovable vertical pins guide the wafer peripheral edge or wall while the wafer is moving up. Depending on the design of the lifting head, lifting of the wafer is stopped by a shoulder (e.g., a conical, angled, or tapered surface of a bushing) on the guide pins.

In operation 1106, at least one arm of the wafer handling assembly is radially retracted so that a wafer engaging mechanism engages the bottom peripheral corner edge of the wafer #1. In operation 1108, the lifting head is deactivated and the wafer #1 stays supported by the wafer engaging mechanism(s).

In operation 1110, the wafer handling assembly, with the wafer #1 supported by the wafer engaging mechanism(s), is moved to a second location where the wafer #1 (processed wafer) is handed off to a wafer aligner or factory transport mechanism such as an end effector. In operation 1112, the wafer engaging mechanism(s) release the held wafer #1 by extending the arm with the wafer engaging mechanism(s) radially outward and dropping the wafer onto, e.g., a wafer aligner or an end effector. In operation 1114, the wafer #1 is moved away from the stationary wafer handling assembly by the factory transport mechanism to another processing position where the wafer #1 is further processed.

In operation 1116, a factory transport mechanism (e.g., a robot with an end effector) brings in a new unprocessed wafer (wafer #2) under the wafer handling assembly stationed in the second location. In operation 1118, the non-contact lifting head is activated, lifting the wafer into the wafer handling assembly. In operation 1120, the at least one arm retracts radially inward grabbing the wafer #2 with the wafer engaging mechanism(s), and the after that the lifting head is deactivated.

In operation 1122, the entire wafer handling assembly with the wafer #2 supported by the wafer engaging mechanism(s) is moved from the second location back to the original first location. Either prior to or after operation 1122, the substrate carrier at the first location is exchanged for a different (new or clean) carrier.

In operation 1124, the arms extend radially outward, dropping the wafer #2 into the new carrier. In operation 1126, the new carrier with unprocessed wafer #2 is moved to a third location (e.g., processing position) by factory transport mechanism such as an end effector.

The method 1100 is an exemplary method of utilizing a wafer handling assembly having a vertical lifting head and radially extending arm(s) to move a wafer out of a recess in a carrier. The wafer handling assembly can be used for alternate methods.

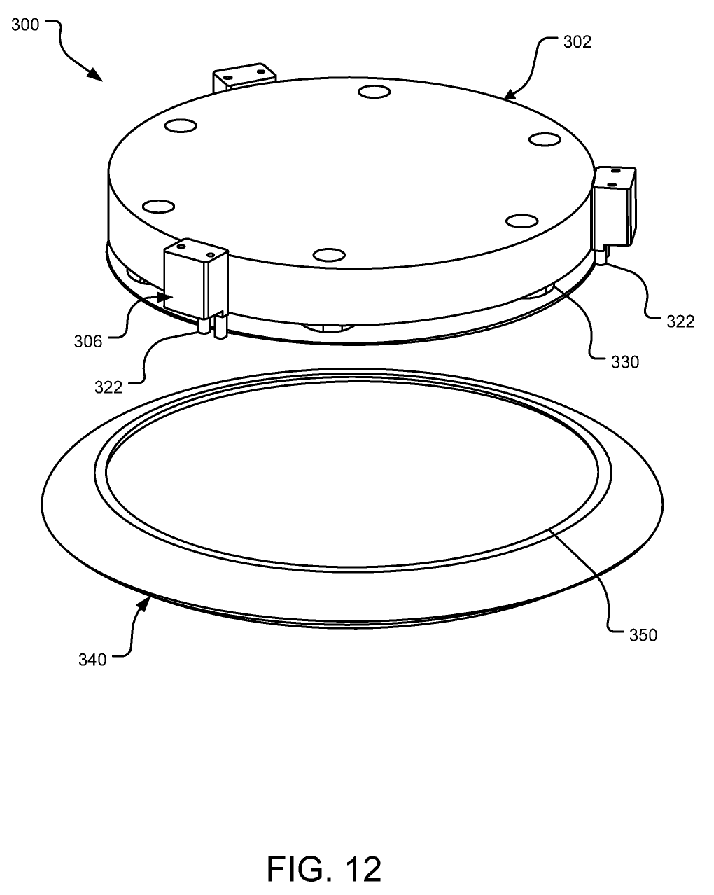

FIGS. 12 through 14 illustrate a third implementation of a wafer handling assembly 300 configured for removing and/or placing a wafer (e.g., a silicon wafer, a sapphire wafer) onto a wafer carrier. Unless indicated otherwise, the various features and/or elements of the assembly 300 are the same as or similar to the like-number features and/or elements of the assembly 100, 200 described above. It should be understood that features and/or elements from one assembly 100, 200, 300 can be incorporated into another assembly 100, 200, 300.

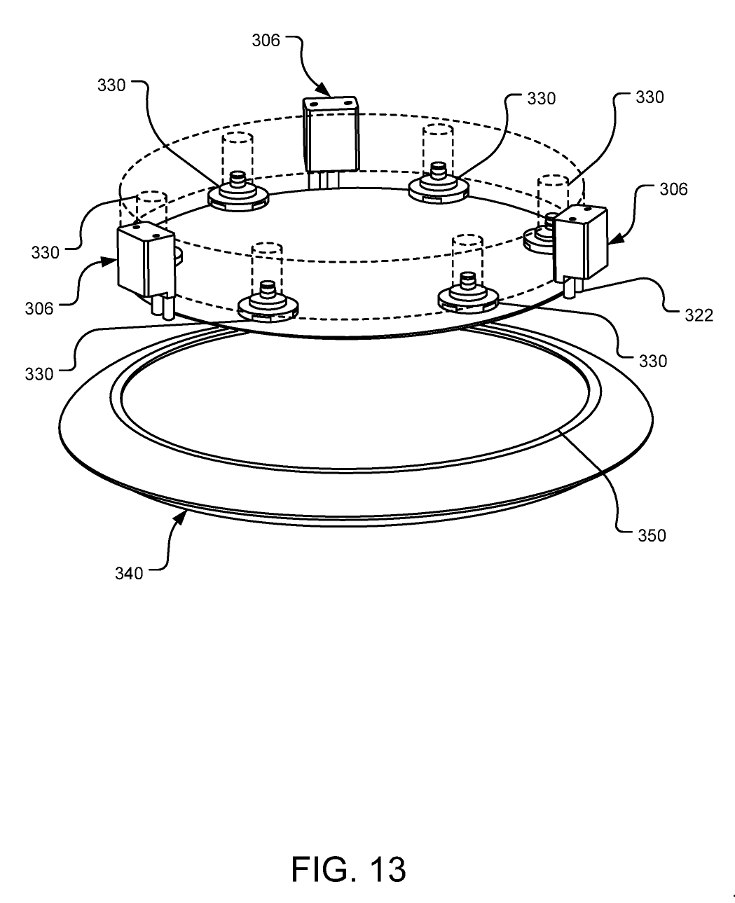

Similar to the wafer handling assemblies 100, 200 the wafer handling assembly 300 (best seen in FIGS. 12 and 13) has a center hub 302 from which extends at least one wafer engaging mechanism 306 and at least one lifting head 330. The figures also illustrate a substrate carrier 340 with a wafer 350. In the particular implementation, the wafer handling assembly 300 has three equally spaced wafer engaging mechanisms 306 and six equally spaced lifting heads 330. Each of the wafer engaging mechanisms 306 has a portion that is radially extendible out from and retractable in toward the center hub 302.

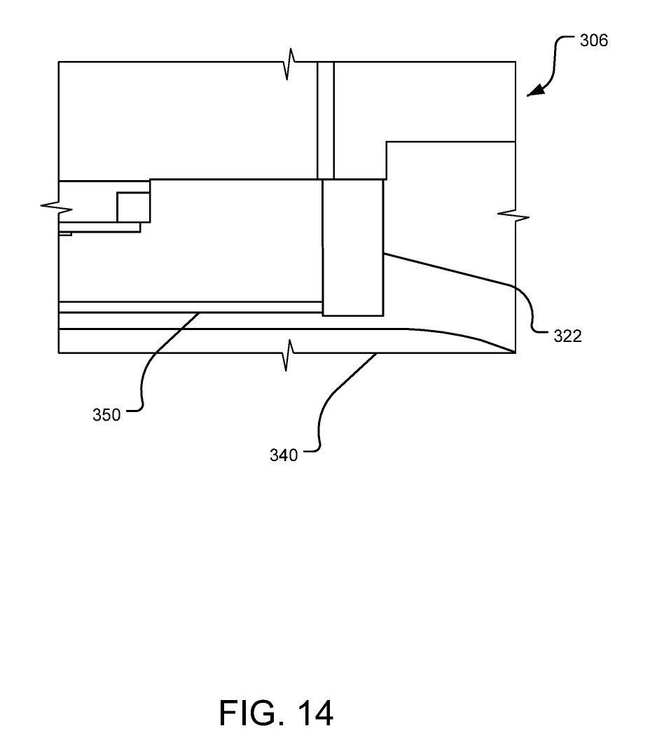

In this implementation, the wafer engaging mechanism 306 does not include a foot on which is supported the wafer 350 but rather includes a pin 322, in some implementations multiple pins 322 (e.g., two pins 322, three pins 322) to support the wafer 350 by its peripheral side edge. FIG. 14 illustrates the peripheral side wall of the wafer 350 engaged by the pin 322. The pins 322 also function as an alignment feature to center and laterally constrain the wafer 350. Unlike the assemblies 100, 200, no portion of the wafer engaging mechanism 306 engages with a top or bottom surface of the wafer 350, nor with a peripheral corner edge of the wafer.

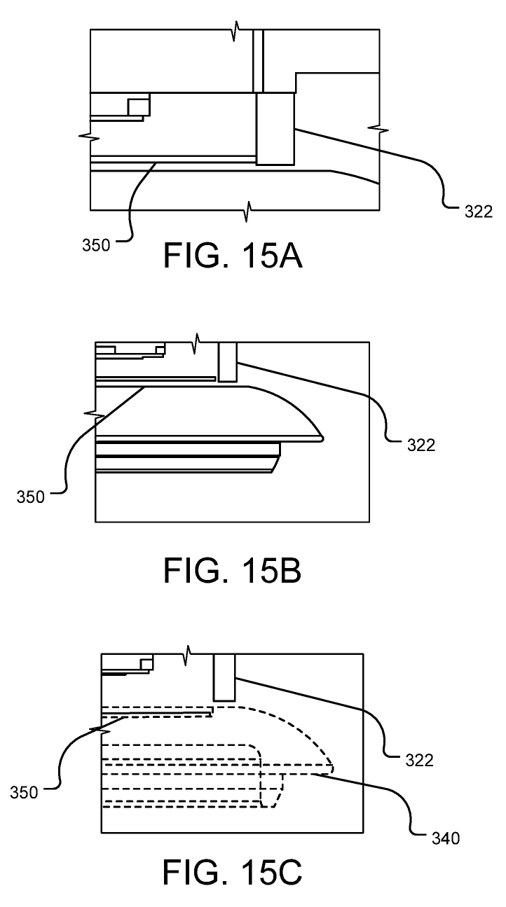

FIGS. 15A, 15B and 15C illustrate a method for placing a wafer into a recess of a substrate carrier using a wafer handling assembly such as assembly 300. In FIG. 15A, the pin 322 retains the wafer 350 by applying radially inward pressure against the side edge of the wafer 350, thus holding the wafer 350. In the FIG. 15B, the pin 322 is shown radially outwardly expanded, thus releasing its hold on the wafer 350. In FIG. 15C the wafer 350 is shown dropped into the recess in the carrier 340 (the carrier 340 shown in phantom to illustrate the wafer 350 in the recess). The pin(s) 322 act as a guide as the wafer drops into the recess.

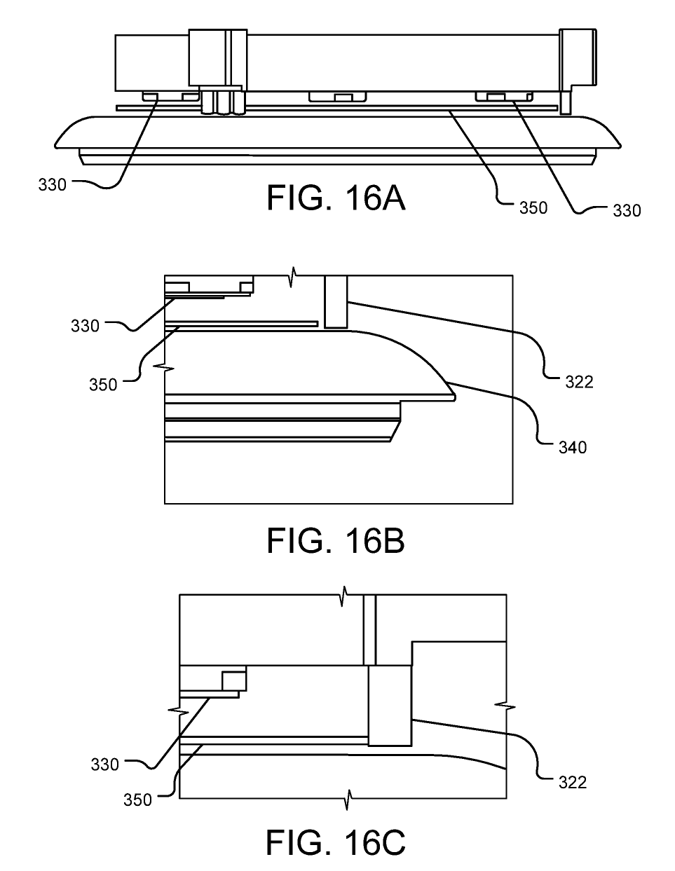

FIGS. 16A, 16B and 16C illustrate a method for lifting a wafer out from a recess of a substrate carrier using a wafer handling assembly such as assembly 300. In FIG. 16A, the wafer 350 has been picked out of the recess of the carrier by the lifting heads 330. As seen in FIG. 16A, the lifting heads 330 are non-contact lifting heads, creating no physical contact with the top surface of the wafer 350. In FIG. 16B, a pin 322 is illustrated guiding the wafer 350 out of the recess. In FIG. 16C, the pin 322 radially retracts inward, contacting and gripping the side edge of the wafer 350. After the pin 322 grabs the wafer 350, the lifting head 330 is disengaged (e.g., turned off).

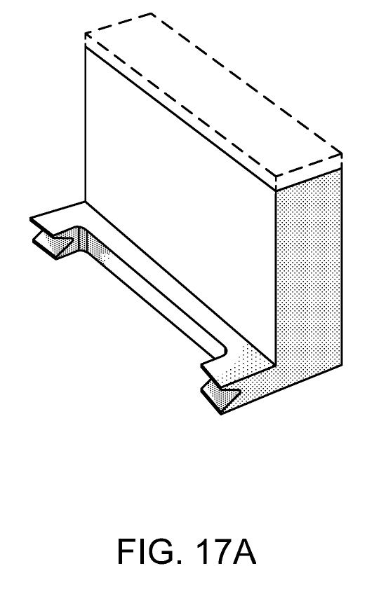

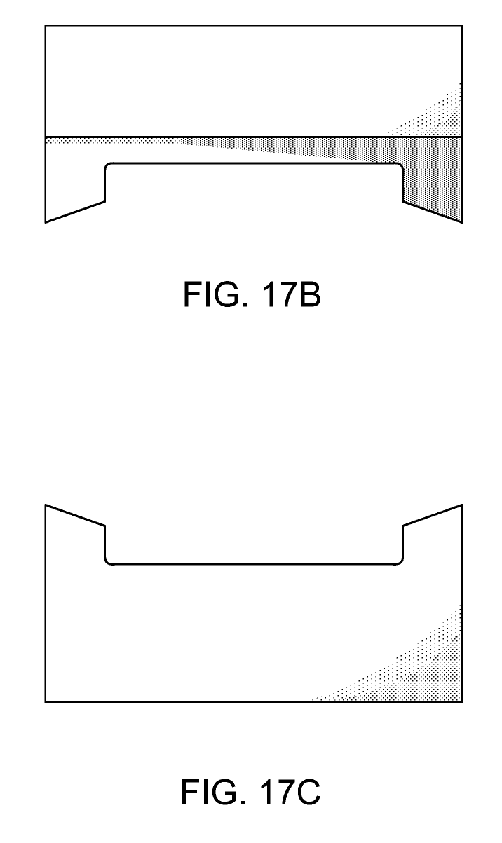

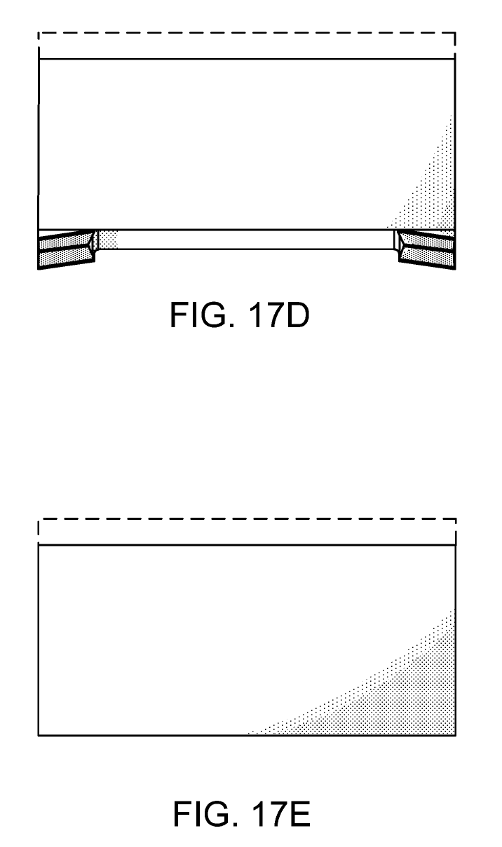

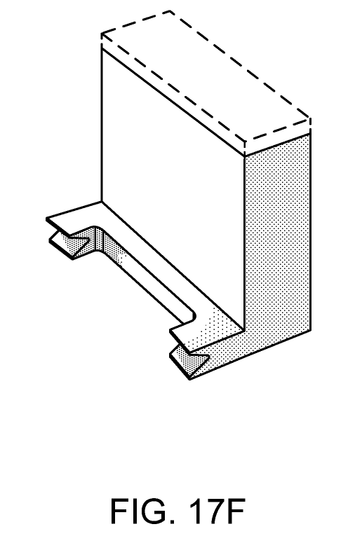

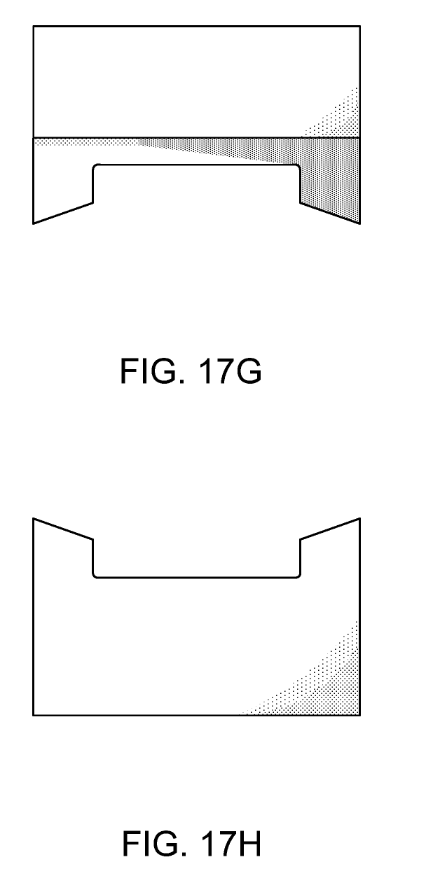

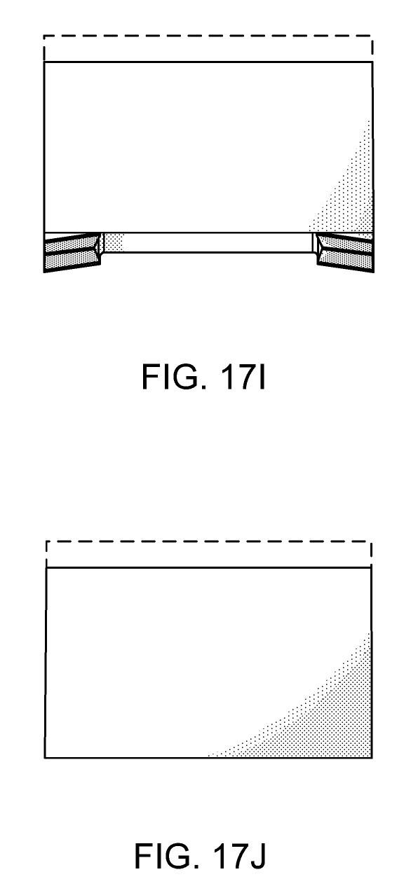

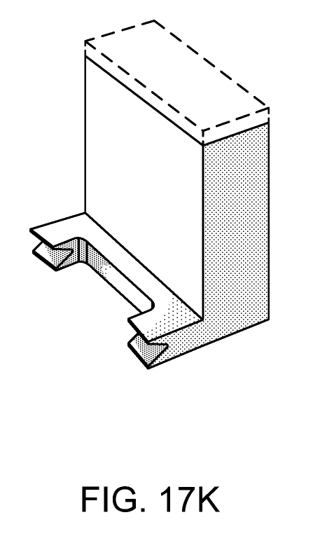

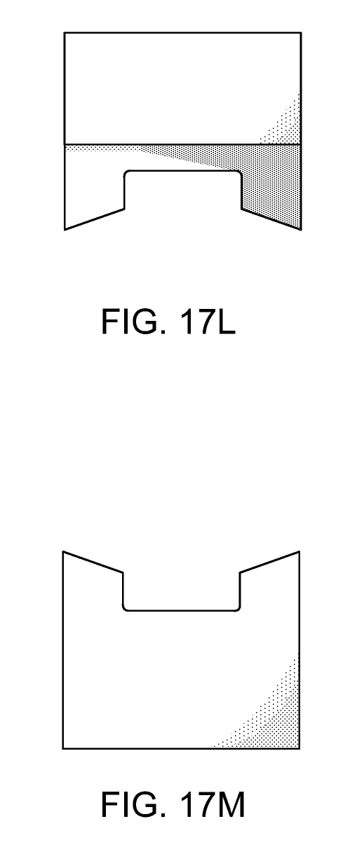

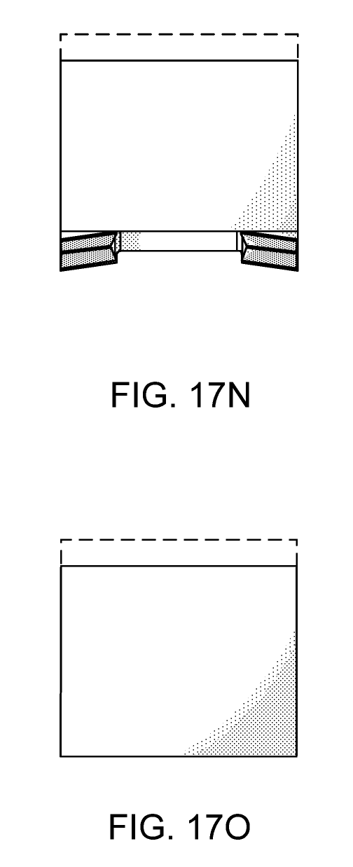

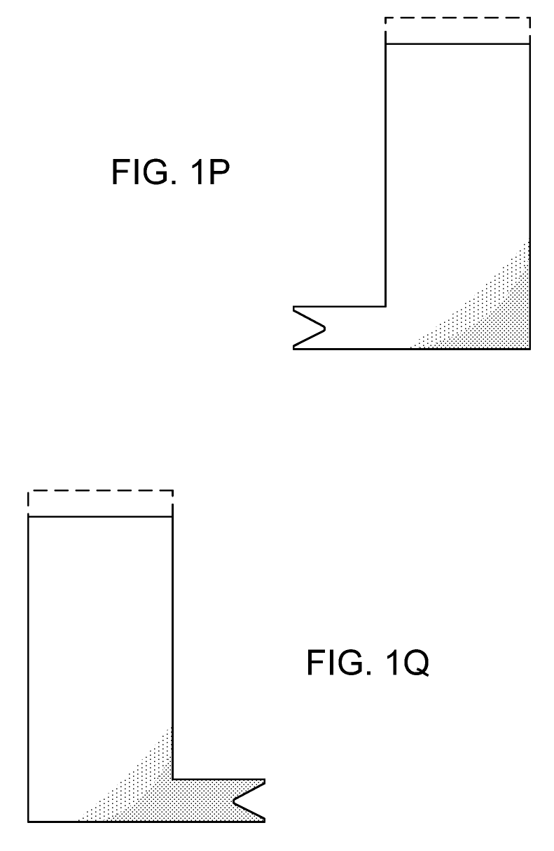

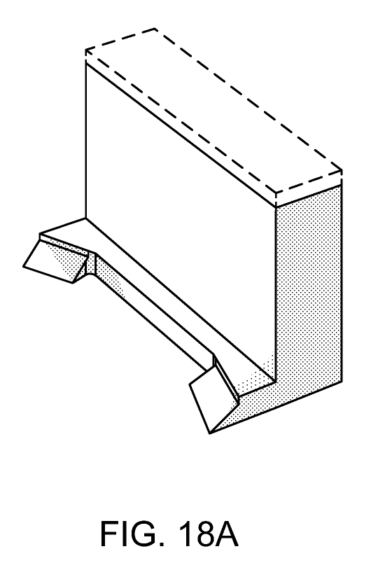

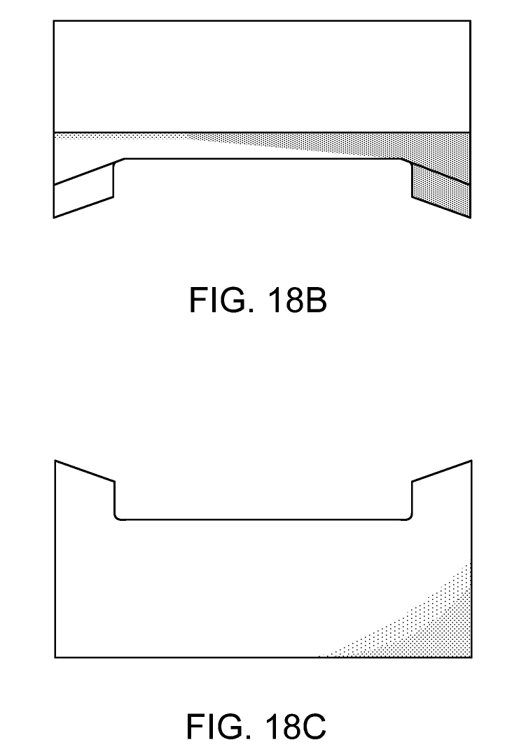

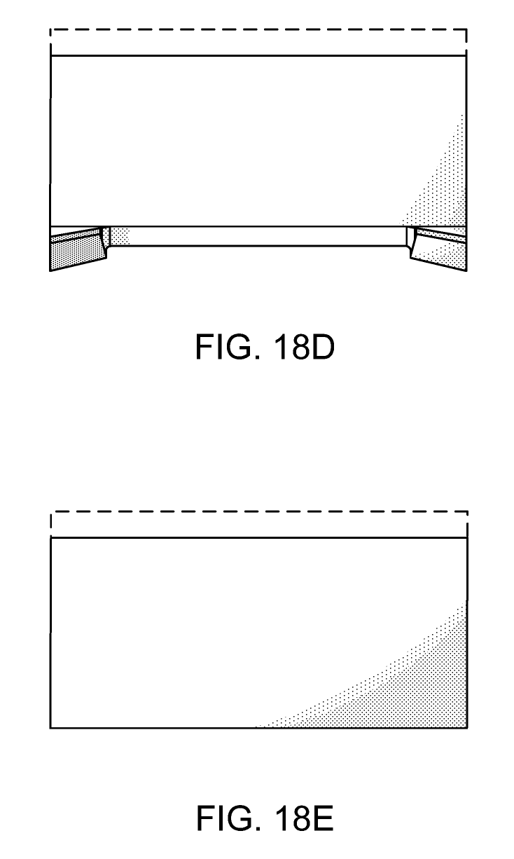

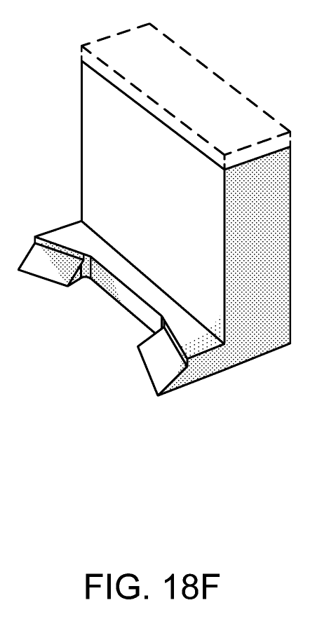

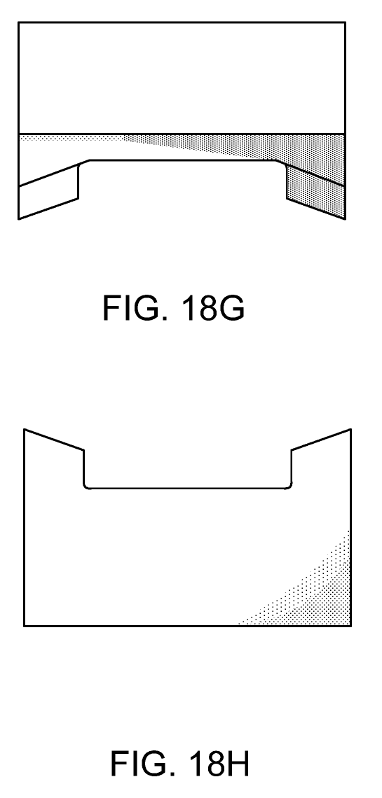

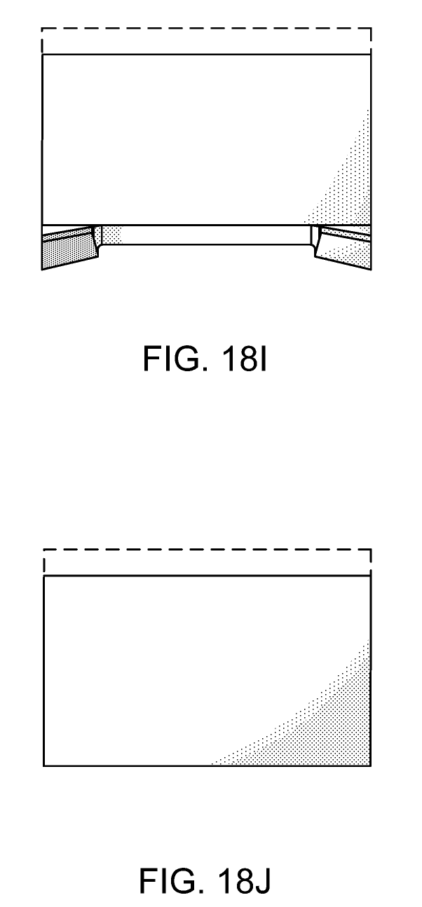

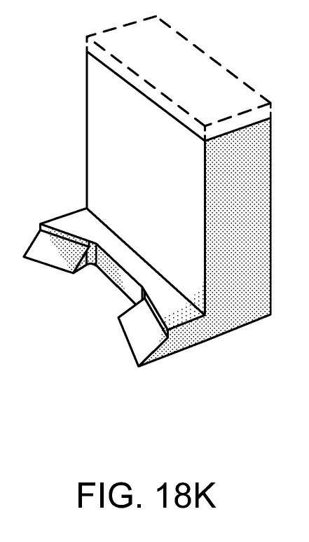

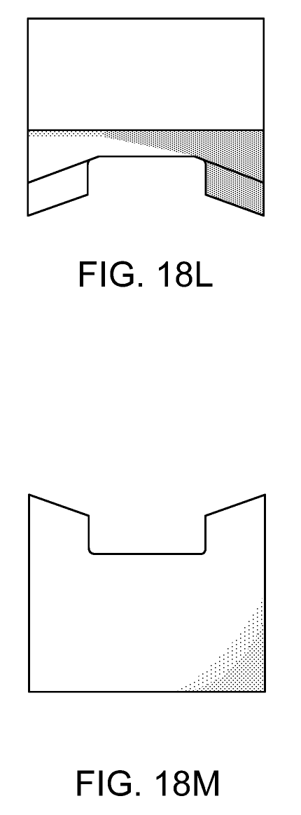

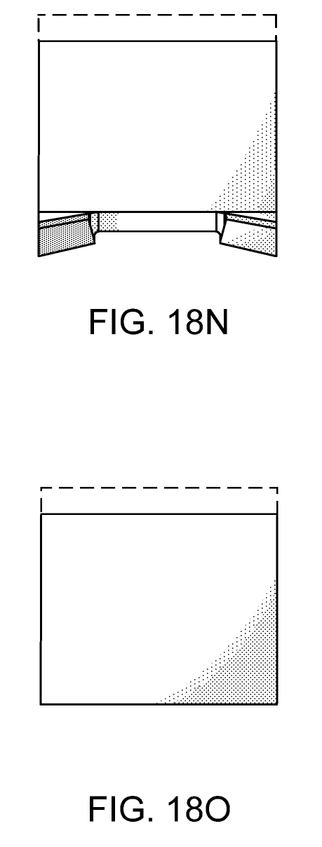

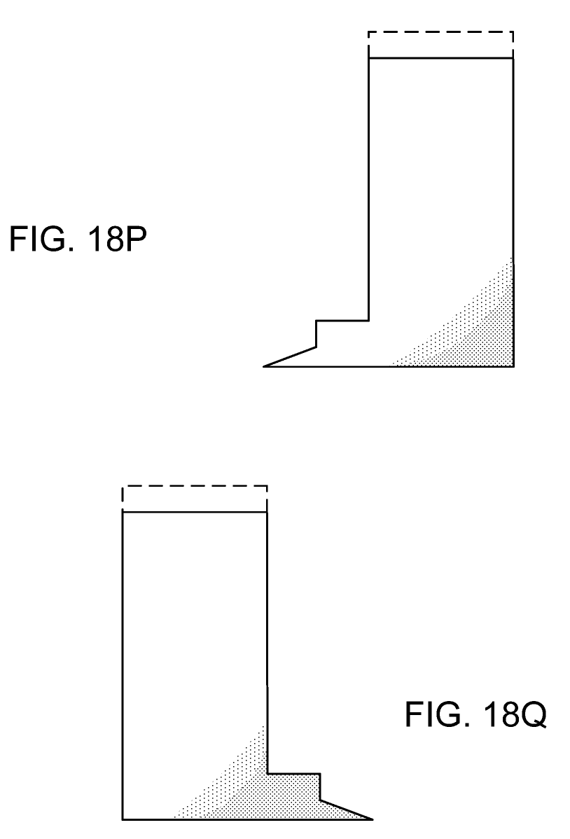

The final sets of figures illustrate various alternate embodiments of certain parts of the wafer handling assemblies 100, 200, 300 and variants thereof. For example, FIGS. 17A-17Q and FIGS. 18A-18Q show numerous embodiments of wafer engaging mechanisms.

FIG. 17A is a perspective view of a first embodiment of a wafer engaging mechanism, FIG. 17B is a top view, FIG. 17C is a bottom view, FIG. 17D is a front view, and FIG. 17E is a back view. FIG. 17F is a perspective view of a second embodiment of a wafer engaging mechanism, FIG. 17G is a top view, FIG. 17H is a bottom view, FIG. 17I is a front view, and FIG. 17J is a back view. FIG. 17K is a perspective view of a third embodiment of a wafer engaging mechanism, FIG. 17L is a top view, FIG. 17M is a bottom view, FIG. 17N is a front view, and FIG. 17O is a back view. FIG. 17P and FIG. 17Q are a left side view and a right side view, respectively, of each of the the wafer engaging mechanisms of FIG. 17A, FIG. 17F and FIG. 17K.

FIG. 18A is a perspective view of a fourth embodiment of a wafer engaging mechanism, FIG. 18B is a top view, FIG. 18C is a bottom view, FIG. 18D is a front view, and FIG. 18E is a back view. FIG. 18F is a perspective view of a fifth embodiment of a wafer engaging mechanism, FIG. 18G is a top view, FIG. 18H is a bottom view, FIG. 18I is a front view, and FIG. 18J is a back view. FIG. 18K is a perspective view of a sixth embodiment of a wafer engaging mechanism, FIG. 18L is a top view, FIG. 18M is a bottom view, FIG. 18N is a front view, and FIG. 18O is a back view. FIG. 18P and FIG. 18Q are a left side view and a right side view, respectively, of each of the the wafer engaging mechanisms of FIG. 18A, FIG. 18F and FIG. 18K.

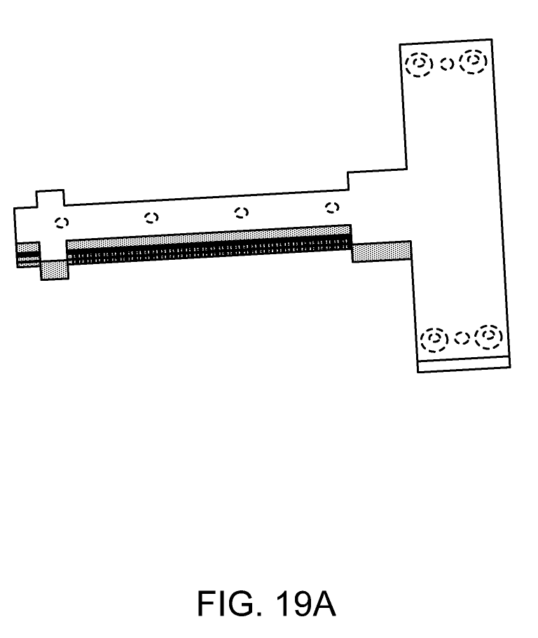

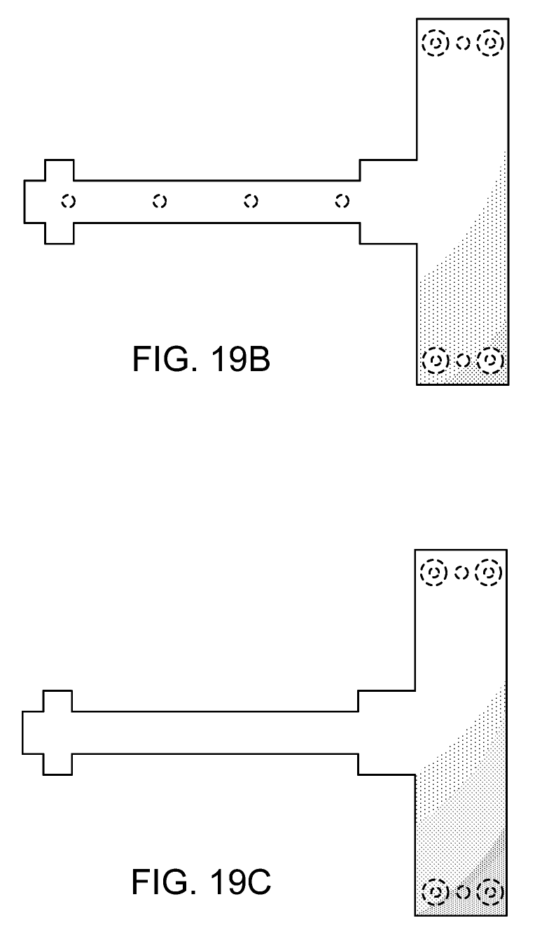

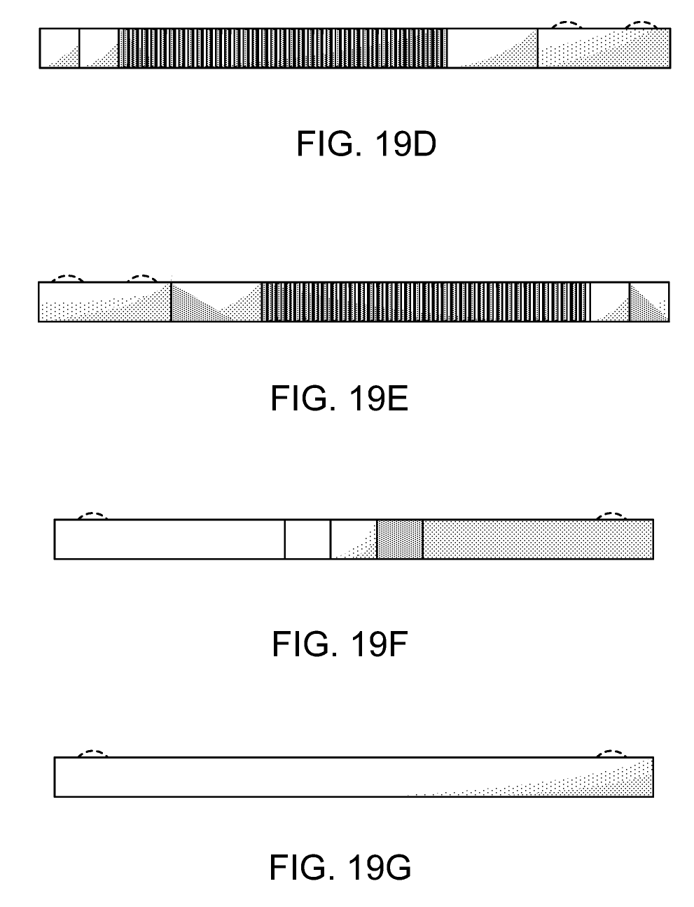

FIG. 19A is a perspective view of a slideable member, FIG. 19B is a top view, FIG. 19C is a bottom view, FIG. 19D is a left side view, FIG. 19E is a right side view, FIG. 19F is a front view, and FIG. 19G is a back view.

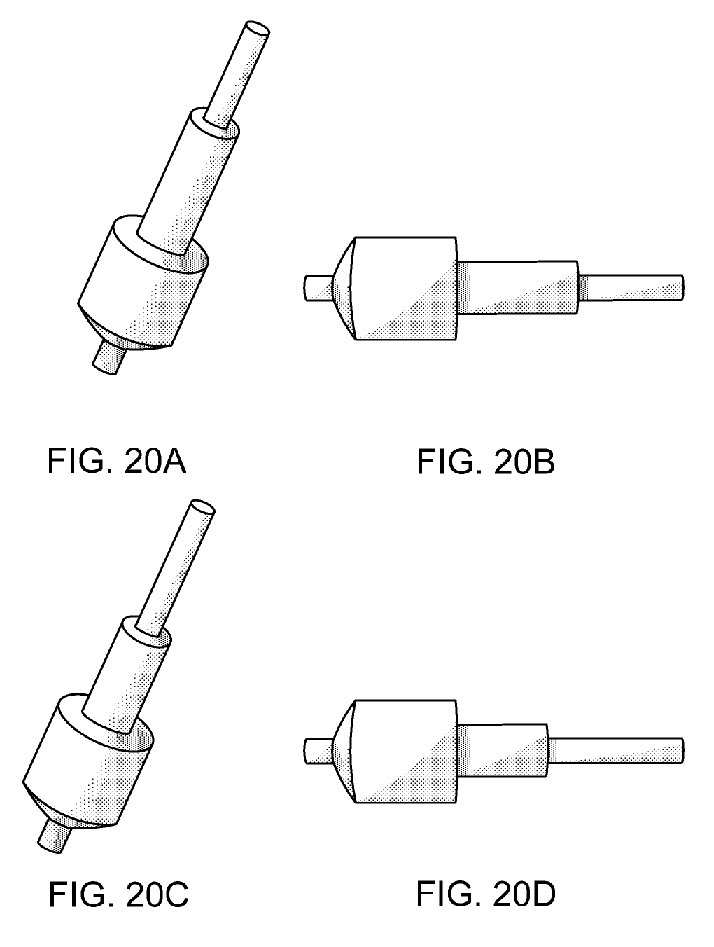

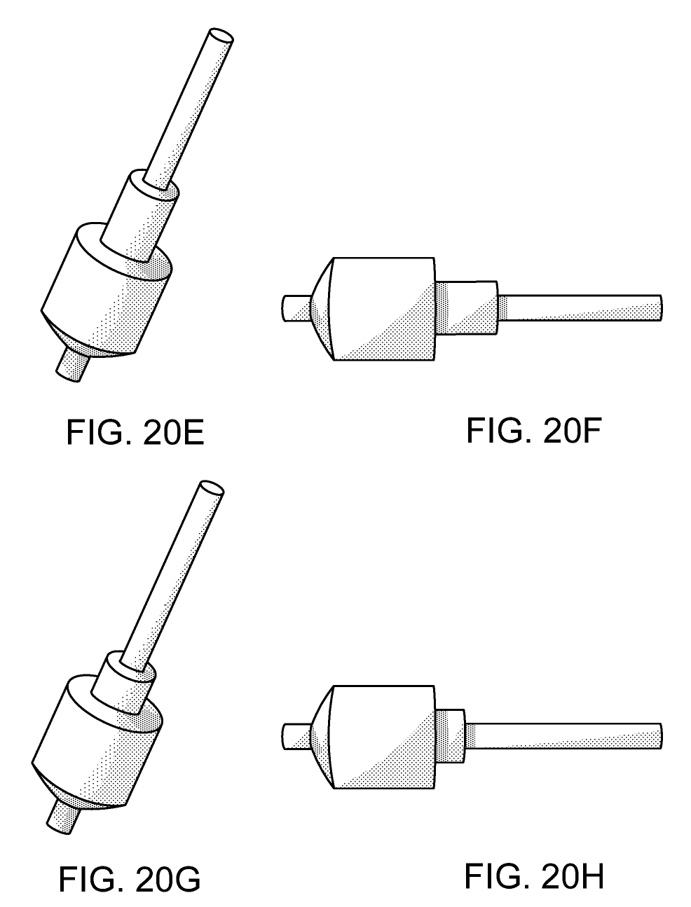

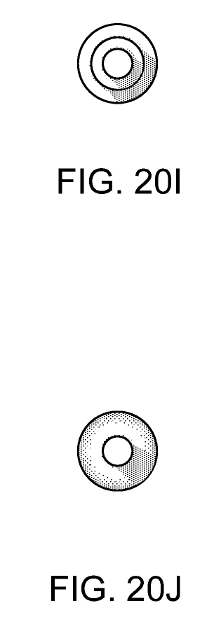

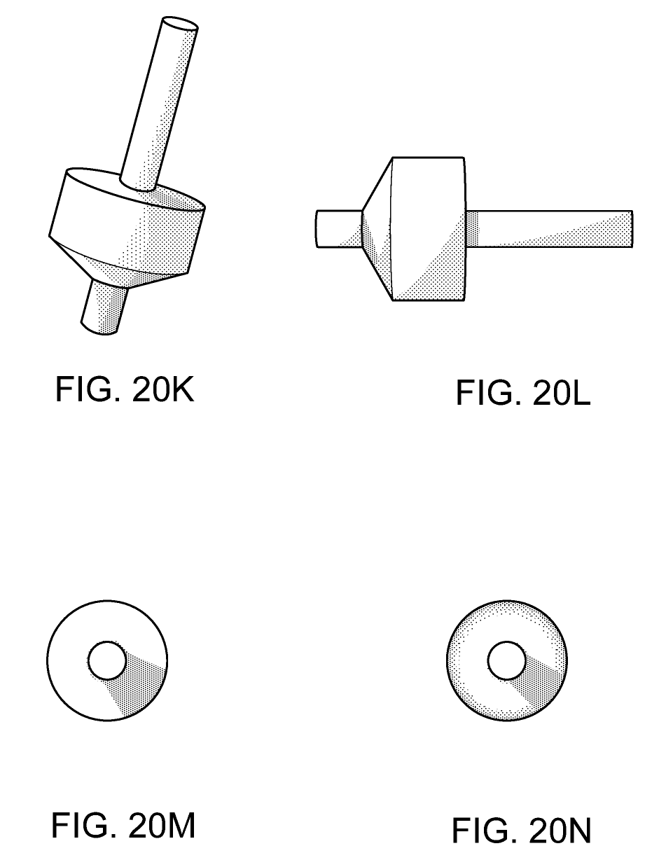

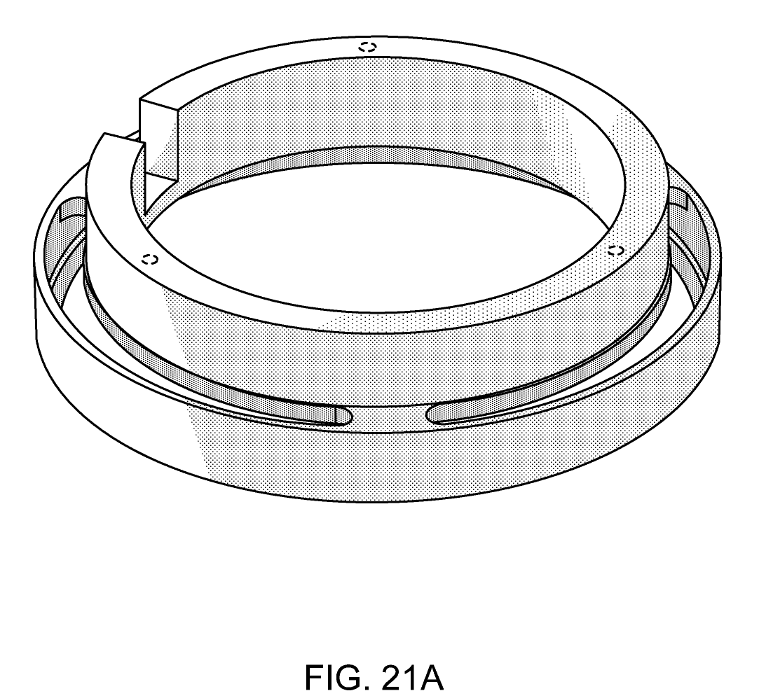

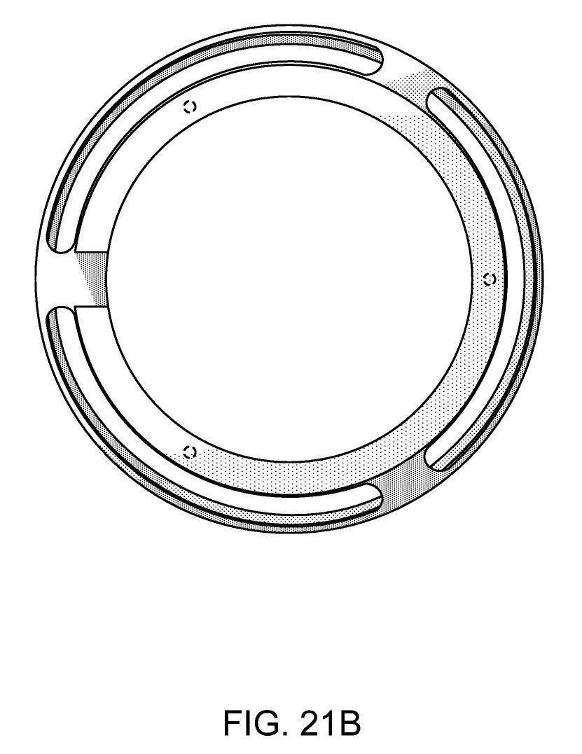

FIG. 20A is a perspective view of a first embodiment of an alignment member, and FIG. 20B is a left side view of the alignment member of FIG. 20A, with each of the right side view, front view and back view being the same. FIG. 20C is a perspective view of a second embodiment of an alignment member, and FIG. 20D is a left side view of the alignment member of FIG. 20C, with each of the right side view, front view and back view being the same. FIG. 20E is a perspective view of a third embodiment of an alignment member, and FIG. 20F is a left side view of the alignment member of FIG. 20E, with each of the right side view, front view and back view being the same. FIG. 20G is a perspective view of a fourth embodiment of an alignment member, and FIG. 20H is a left side view of the alignment member of FIG. 20G, with each of the right side view, front view and back view being the same. FIG. 20I is a top view and FIG. 20J is a bottom view of each of the alignment members of FIG. 20A, FIG. 20C, FIG. 20E and FIG. 20G.

FIG. 20K is a perspective view of a fifth embodiment of an alignment member, and FIG. 20L is a left side view of the alignment member of FIG. 20K, with each of the right side view, front view and back view being the same. FIG. 20M is a top view and FIG. 20N is a bottom view of the alignment member of FIG. 20K.

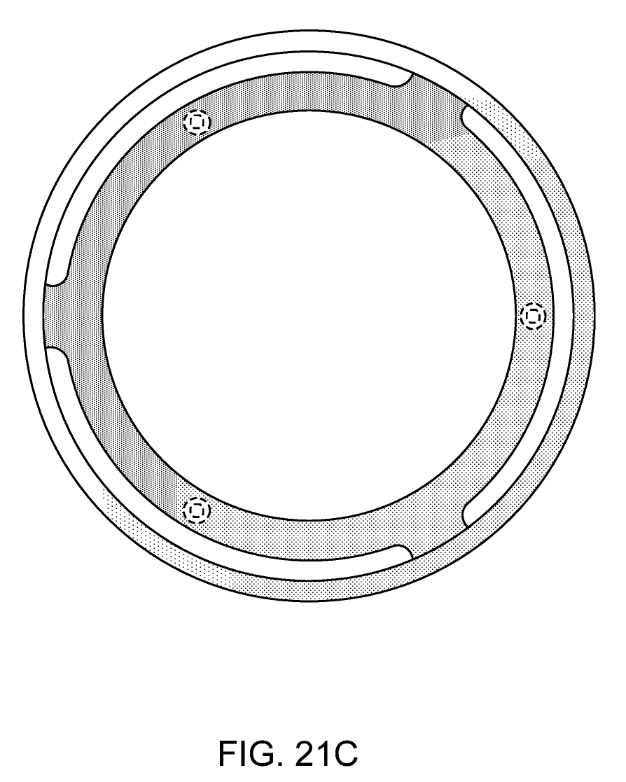

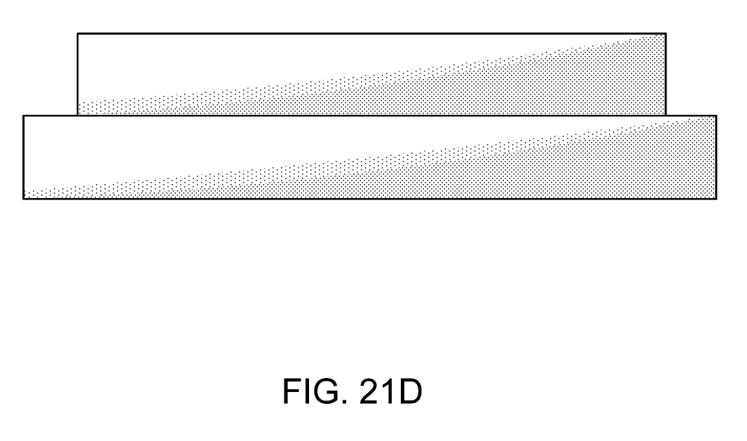

FIG. 21A is a perspective view of a shroud, FIG. 21B is a top view, FIG. 21C is a bottom view, and FIG. 21D is left side view, with each of the right side view, front view and back view being the same.

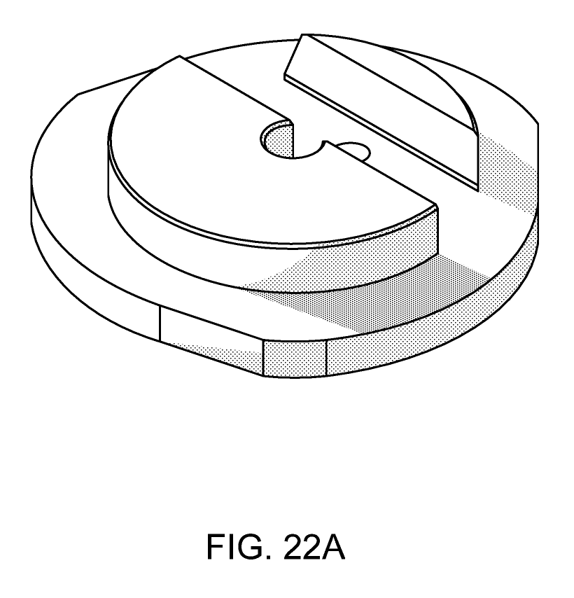

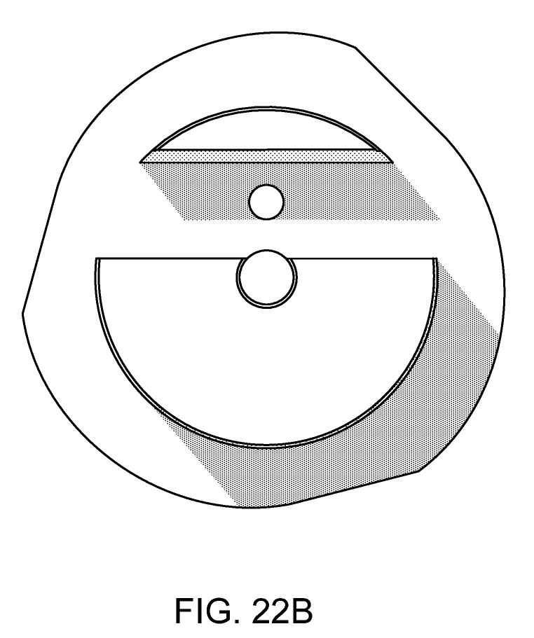

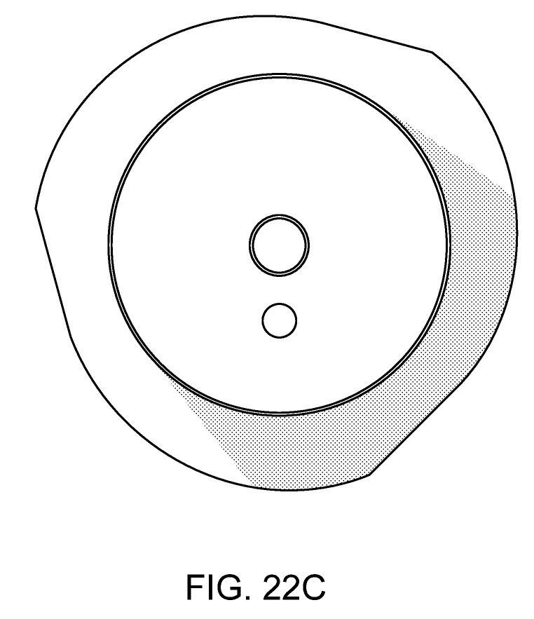

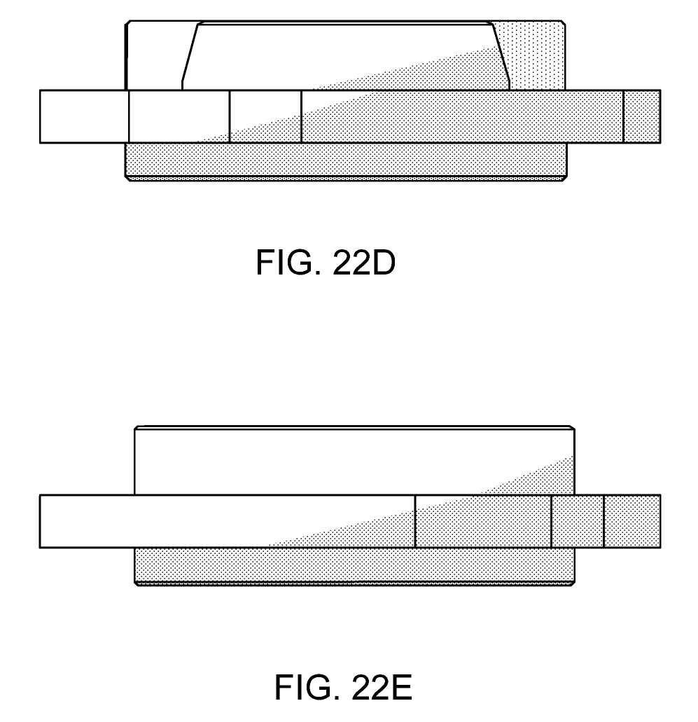

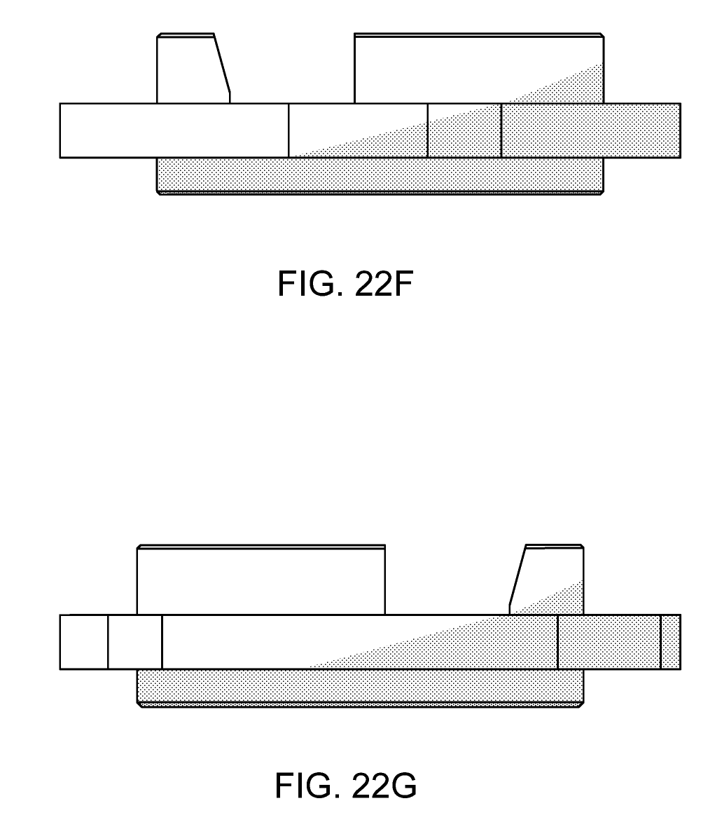

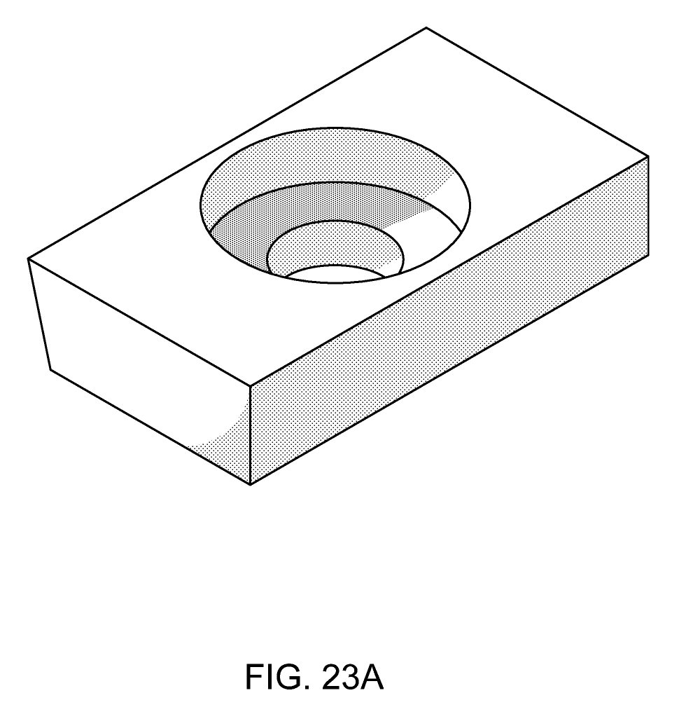

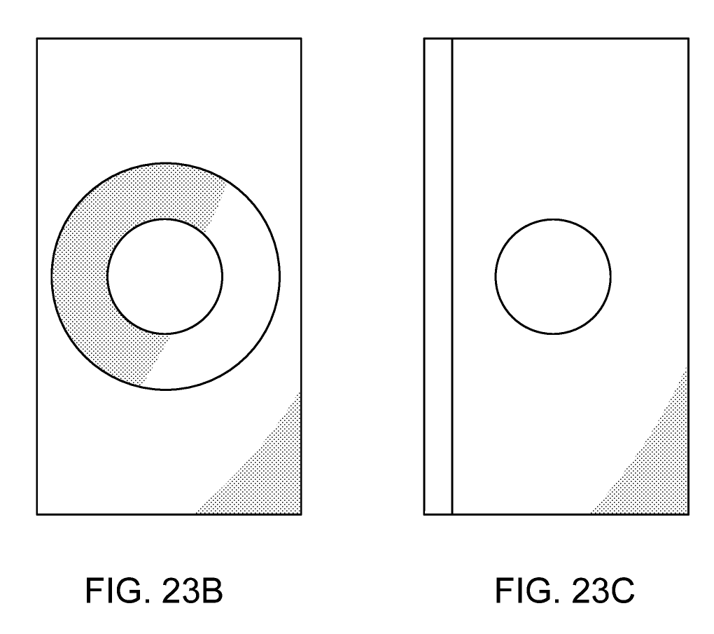

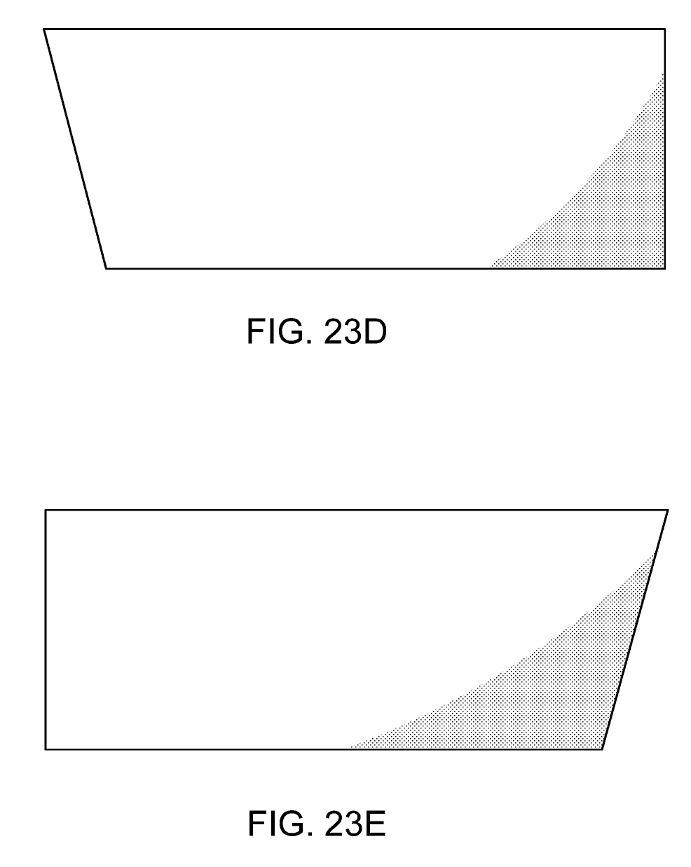

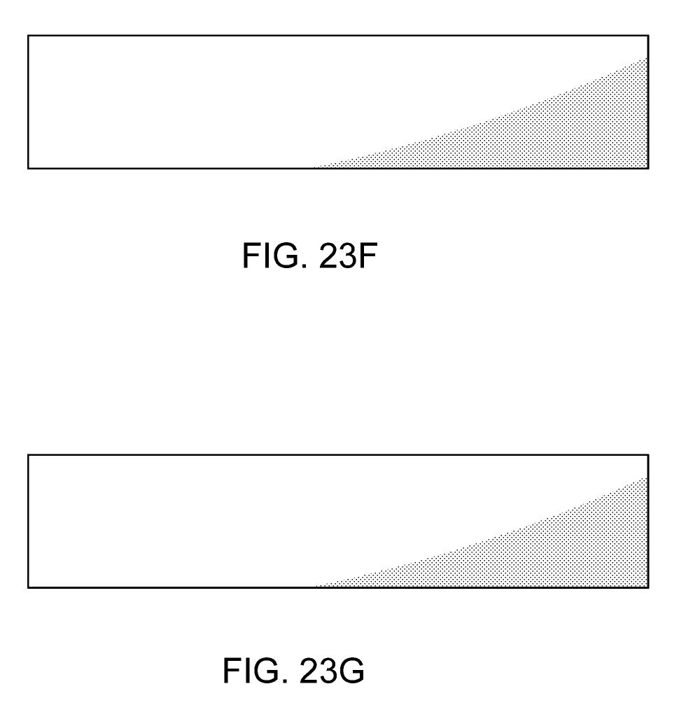

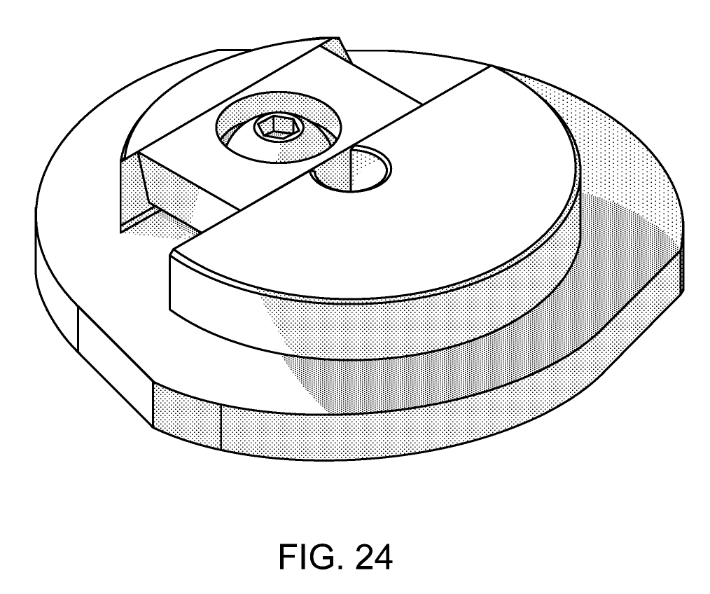

FIG. 22A is a perspective view of a first part of a rotatable cam, FIG. 22B is a top view, FIG. 22C is a bottom view, FIG. 22D is left side view, FIG. 22E is right side view, FIG. 22F is front view, and FIG. 22G is a back view. FIG. 23A is a perspective view of a second part of a rotatable cam, FIG. 23B is a top view, FIG. 23C is a bottom view, FIG. 23D is left side view, FIG. 23E is right side view, FIG. 23F is front view, and FIG. 23G is a back view. When combined (e.g., with a set screw) the first part and the second part of the rotatable cam is illustrated in FIG. 24.

Thus, various implementations of wafer handling assemblies have been described, including assemblies 100, 200, 300 and variants thereof, to load and unload substrates (wafers) into and out from the recess of a substrate carrier. The carrier, with the wafer retained thereon or therein, is transferred into an appropriate chamber, such as a reactor (e.g., MOCVD reactor) with any suitable transport mechanism for wafer processing; one example of a transport mechanism is a robotic end effector. When processing in the chamber is completed, the carrier with the processed wafer is transferred back to the assembly 100, 200, 300 or variant thereof, by the same or a different transport mechanism. The processed wafer is removed from the recess in the carrier, first by the lifting head and then by the at least one wafer engaging mechanism. The lifted wafer can be transferred to another station (e.g., another reactor) by any suitable transport mechanism.

The above specification and examples provide a complete description of the structure, features and use of exemplary implementations of the invention. Since many embodiments of the invention can be made without departing from the spirit and scope of the invention, the invention resides in the claims hereinafter appended. Furthermore, structural features of the different embodiments may be combined in yet another embodiment without departing from the recited claims.

What is claimed is:

1. A wafer handling assembly comprising:
a center hub supporting a vertical lifting head and at least three radially extending and radially retracting wafer engaging mechanisms each having a surface to engage a wafer at a peripheral edge of the wafer.

2. The assembly of claim 1 wherein each wafer engaging mechanism is supported by a radially extending arm.

3. The assembly of claim 1 wherein each wafer engaging mechanism comprises a foot.

4. The assembly of claim 3 wherein the foot comprises a lower toe and an upper toe defining the wafer receiving region.

5. The assembly of claim 1 wherein each wafer engaging mechanism comprises a pin.

6. The assembly of claim 5 wherein the pin has a shoulder.

7. The assembly of claim 1 wherein the vertical lifting head is a Bernoulli head.

8. The assembly of claim 1 wherein the vertical lifting head is an ultrasonic head.

9. The assembly of claim 1 comprising more than one vertical lifting head.

10. The assembly of claim 1 wherein the wafer engaging mechanisms each having a surface to engage a wafer at a peripheral side edge of the wafer.

11. The assembly of claim 1 wherein the wafer engaging mechanisms each having a surface to engage a wafer at a peripheral corner edge of the wafer.

12. A wafer handling assembly comprising:
a non-contact vertical lifting head;
at least one arm configured to radially extend and radially retract in relation to the lifting head; and
a wafer engaging mechanism comprising a wafer receiving region and an alignment pin at a distal end of the arm, the wafer receiving region defined by a lower toe.

13. The assembly of claim 12 comprising three arms equally spaced around the vertical lifting head configured to radially extend and radially retract, with a wafer engaging mechanism comprising a wafer receiving region and an alignment pin at a distal end of each arm.

14. The assembly of claim 13 wherein the lower toe comprises a sloped surface.

15. The assembly of claim 13 wherein the wafer receiving region is further defined by an upper toe.

16. A method comprising:
providing a wafer on a carrier, the wafer having a top surface, a bottom surface in contact with the carrier, a top peripheral corner edge, a bottom peripheral corner edge, and a peripheral side edge;
non-contactingly engaging the top surface of the wafer with a lifting head;
lifting the wafer from the carrier with the lifting head; and
after lifting the wafer, contacting the bottom peripheral corner edge or peripheral side edge with a wafer engaging mechanism and then releasing the wafer from the lifting head.

17. The method of claim 16 comprising, after lifting the wafer, contacting the peripheral side edge of the wafer with a pin of the wafer engaging mechanism and then releasing the wafer from the lifting head.

18. The method of claim 16 comprising, after lifting the wafer, contacting the peripheral bottom corner edge of the wafer with a foot of the wafer engaging mechanism and then releasing the wafer from the lifting head.
